(19) United States
(12) Patent Application Publication
(10) Pub. No.: US 2021/0057661 A1
(43) Pub. Date: Feb. 25, 2021

(54) Organic photovoltaic cells and compositions thereof

(71) Applicant: The Regents of the University of Michigan, Ann Arbor, MI (US)

(72) Inventors: Stephen R. Forrest, Ann Arbor, MI (US); Xiaozhou Che, Ann Arbor, MI (US); Yongxi Li, Ann Arbor, MI (US)

(21) Appl. No.: 16/963,082

(22) PCT Filed: Jan. 17, 2019
(86) PCT No.: PCT/US2019/013903

§ 371 Date: Jul. 17, 2020

Related U.S. Application Data
(60) Provisional application No. 62/618,729, filed on Jan. 18, 2018.

(51) Int. Cl. H01L 51/42

(52) U.S. Cl. CPC H01L 51/4246; H01L 51/0046

(57) ABSTRACT

Organic photovoltaic cells (OPVs) and their compositions are described herein. In one or more embodiments, the OPV or solar cell includes an anode; a cathode; a first active layer positioned between the anode and the cathode, the first active layer configured to absorb light in a first wavelength spectrum; a second active layer positioned between the anode and the cathode, the second active layer configured to absorb light in a second wavelength spectrum; and a recombination zone positioned between the first active layer and the second active layer.

This application claims the benefit of U.S. Provisional Application No. 62/618,729, filed Jan. 18, 2018, which is hereby incorporated by reference in its entirety.

### STATEMENT REGARDING FEDERALLY SPONSORED RESEARCH

This invention was made with U.S. Government support under Contract Nos. DE-EE0006708 and N00014-17-1-2211 awarded by the U.S. Department of Energy and Office of Naval Research. The government has certain rights in the invention.

### TECHNICAL FIELD

The present disclosure generally relates to electrically active, optically active, solar, and semiconductor devices, and in particular, to organic photovoltaic cells and cathode buffers, tandem cell structures, and interconnecting structures in such organic photovoltaic cells.

### BACKGROUND

Optoelectronic devices rely on the optical and electronic properties of materials to either produce or detect electromagnetic radiation electronically or to generate electricity from ambient electromagnetic radiation.

Photosensitive optoelectronic devices convert electromagnetic radiation into electricity. Solar cells, also called photovoltaic (PV) devices or cells, are a type of photosensitive optoelectronic device that is specifically used to generate electrical power. PV devices, which may generate electrical energy from light sources other than sunlight, may be used to drive power consuming loads to provide, for example, lighting, heating, or to power electronic circuitry or devices such as calculators, radios, computers or remote monitoring or communications equipment. These power generation applications may involve the charging of batteries or other energy storage devices so that operation may continue when direct illumination from the sun or other light sources is not available, or to balance the power output of the PV device with the specific applications requirements.

Traditionally, photosensitive optoelectronic devices have been constructed of a number of inorganic semiconductors, e.g., crystalline, polycrystalline and amorphous silicon, gallium arsenide, cadmium telluride, and others.

More recent efforts have focused on the use of organic photovoltaic (OPV) cells to achieve acceptable photovoltaic conversion efficiencies with economical production costs. OPVs offer a low-cost, light-weight, and mechanically flexible route to solar energy conversion. Compared with polymers, small molecule OPVs share the advantage of using materials with well-defined molecular structures and weights. This leads to a reliable pathway for purification and the ability to deposit multiple layers using highly controlled thermal deposition without concern for dissolving, and thus damaging, previously deposited layers or sub-cells.

An obstacle to OPV commercialization is that the power conversion efficiency (PCE) is less than the reported benchmark for market viability of 15%. Historically, the efficiency of OPVs has largely been driven by the choice of acceptors. In the 1980s and 1990s, efficiencies using high electron affinity perylene based compounds were ˜1%. This was followed by the introduction of solution- and vapor-deposited fullerene acceptors. By pairing such acceptors with a range of donors, OPV efficiencies rapidly advanced from 3% to ˜10%. Non-fullerene acceptors (NFAs) have now opened a new avenue for improved optical coverage and energetic pairing with the wide diversity of donor molecules that have been developed over this same time period, pushing the efficiency to ˜13%.

### SUMMARY

Organic photovoltaic cells (OPVs) and their compositions are described herein. In one or more embodiments, the OPV or solar cell includes: an anode; a cathode; a first active layer positioned between the anode and the cathode, the first active layer configured to absorb light in a first wavelength spectrum; a second active layer positioned between the anode and the cathode, the second active layer configured to absorb light in a second wavelength spectrum; and a recombination zone positioned between the first active layer and the second active layer.

In another embodiment, a recombination zone for a multi junction solar cell includes: a plurality of layers positioned between a first active layer and a second active layer of the solar cell, wherein the plurality of layers of the recombination zone is configured to provide a hydrophilic-hydrophobic interface to prevent solvent penetration from the second active layer into the first active layer.

In yet another embodiment, the OPV or solar cell includes: an anode; a cathode; an active layer positioned between the anode and the cathode; and a cathode buffer layer positioned between the cathode and the active layer, wherein the cathode buffer layer includes one or more of the following molecules:

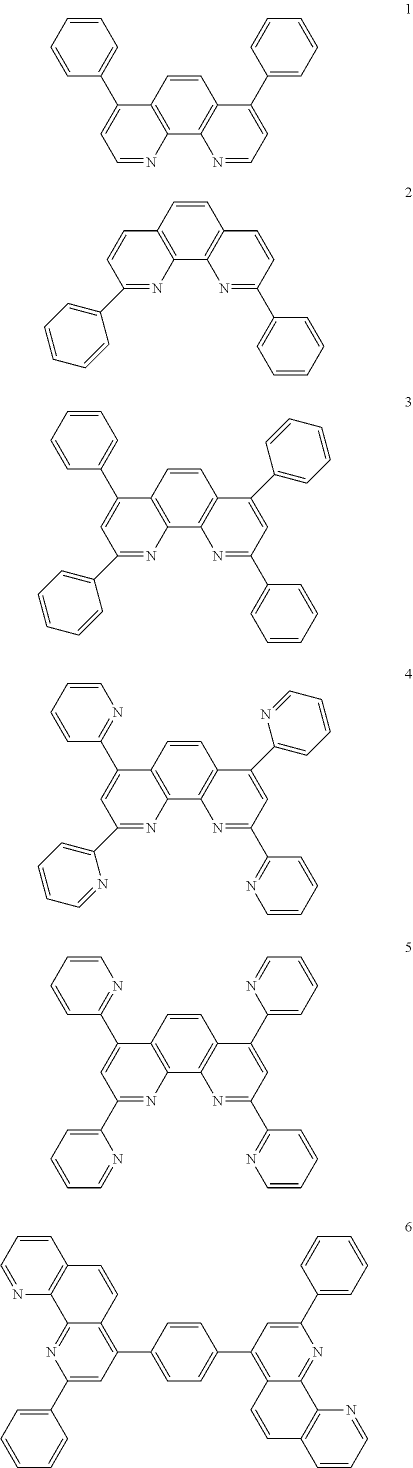

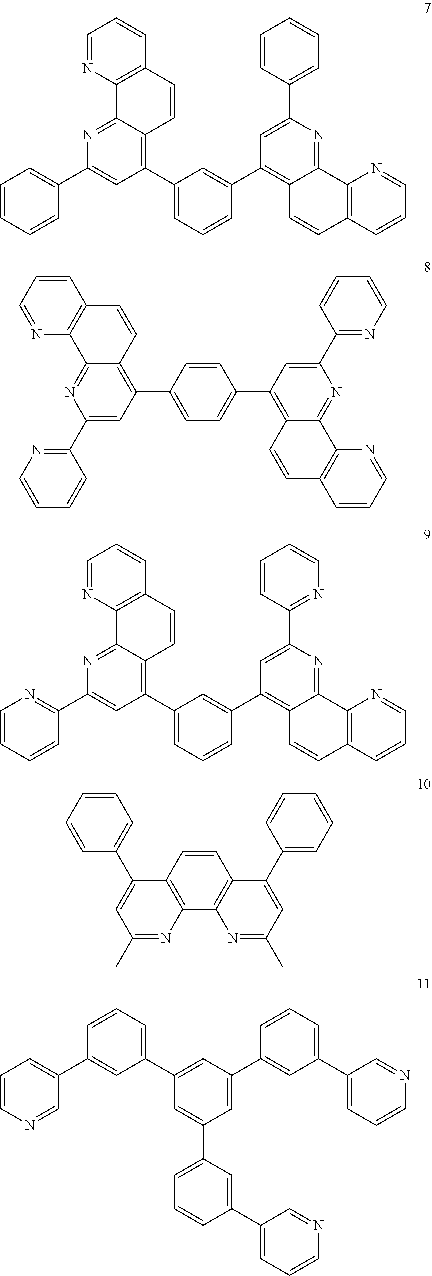

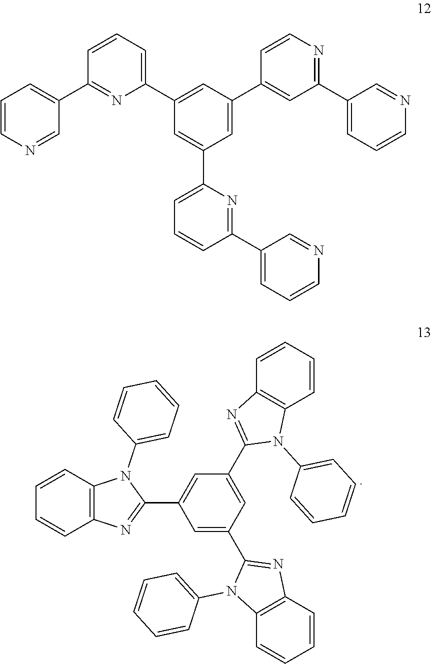

In one embodiment, with reference to one or more of the embodiments above, the solar cell further includes a third active layer positioned between the anode and the cathode, the third active layer configured to absorb light in a third wavelength spectrum; and an additional recombination zone positioned between the second active layer and the third active layer.

In one embodiment, with reference to one or more of the embodiments above, the solar cell further includes at least one additional active layer positioned between the anode and the cathode, the at least one additional active layer configured to absorb light in at least one additional wavelength spectrum; and a corresponding number of additional recombination zones positioned between adjacent active layers.

In one embodiment, with reference to one or more of the embodiments above, the first wavelength spectrum comprises at least a portion of a visible light spectrum, and the second wavelength spectrum comprises at least a portion of a near-infrared light spectrum.

In one embodiment, with reference to one or more of the embodiments above, the first wavelength spectrum includes light with a wavelength range of 400-700 nm.

In one embodiment, with reference to one or more of the embodiments above, the second wavelength spectrum includes light with a wavelength range of 600-900 nm.

In one embodiment, with reference to one or more of the embodiments above, the first wavelength spectrum is adjacent to the second wavelength spectrum.

In one embodiment, with reference to one or more of the embodiments above, the first wavelength spectrum at least partially overlaps with the second wavelength spectrum.

In one embodiment, with reference to one or more of the embodiments above, the first active layer is positioned between the anode and the recombination zone.

In one embodiment, with reference to one or more of the embodiments above, the first active layer comprises a fullerene acceptor.

In one embodiment, with reference to one or more of the embodiments above, the fullerene acceptor is C₆₀ or C₇₀.

In one embodiment, with reference to one or more of the embodiments above, the first active layer is formed by vacuum thermal evaporation.

In one embodiment, with reference to one or more of the embodiments above, the second active layer is positioned between the cathode and the recombination zone.

In one embodiment, with reference to one or more of the embodiments above, the second active layer comprises a non-fullerene acceptor comprising one of the following structures:

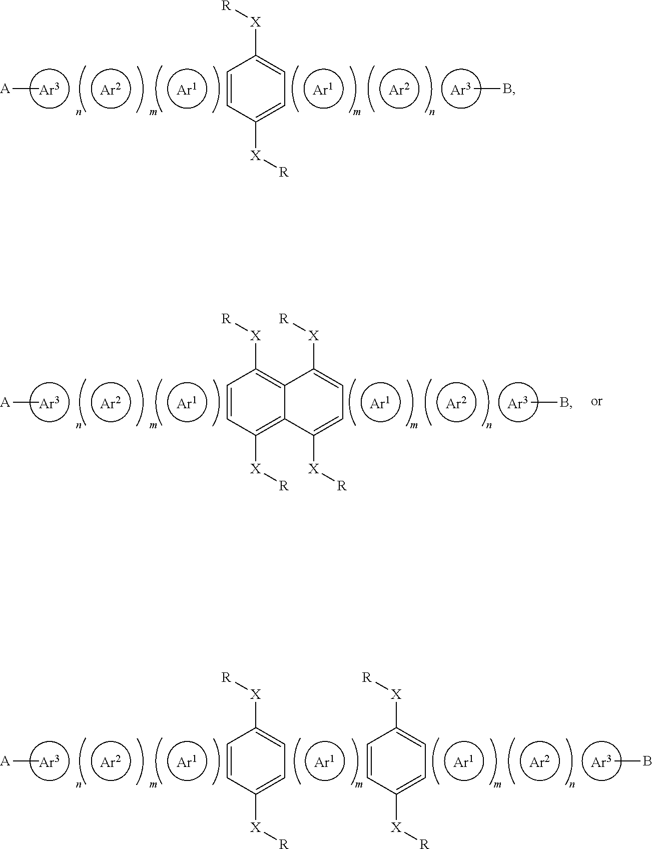

wherein:

A or B is individually selected from the group consisting of:

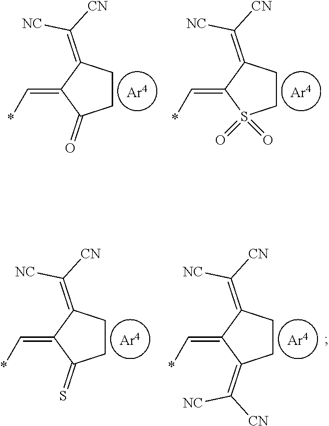

each Ar¹ is individually selected from the group consisting of:

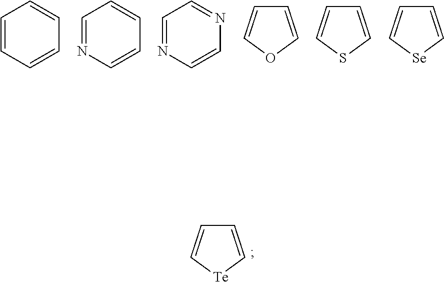

each Ar² is individually selected from the group consisting of:

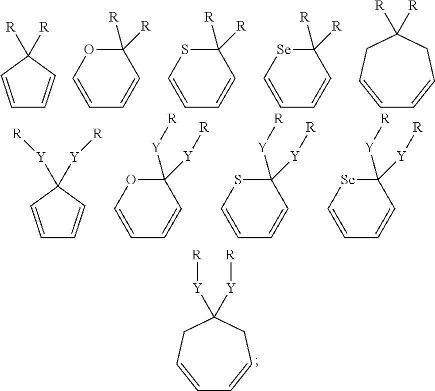

each Ar³ is individually selected from the group consisting of:

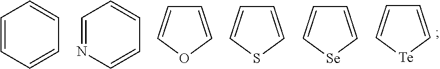

each Ar⁴ is individually selected from the group consisting of:

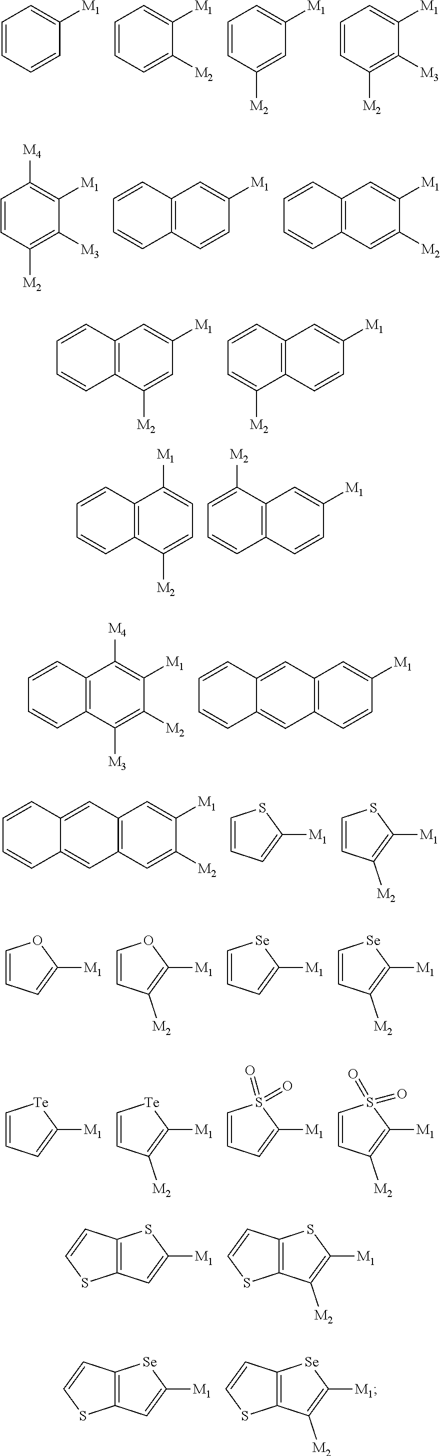

M₁-M₄ are individually selected from the group consisting of hydrogen, fluorine, chlorine, bromine, iodine, astatine, and a cyano group, wherein at least one of M₁-M₄ is a halogen;

each R is individually a C₁-C₂₀ hydrocarbon or an aromatic hydrocarbon;

each X is individually selected from the group consisting of oxygen, carbon, hydrogen, sulfur, selenium, and nitrogen;

each Y is individually selected from the group consisting of:

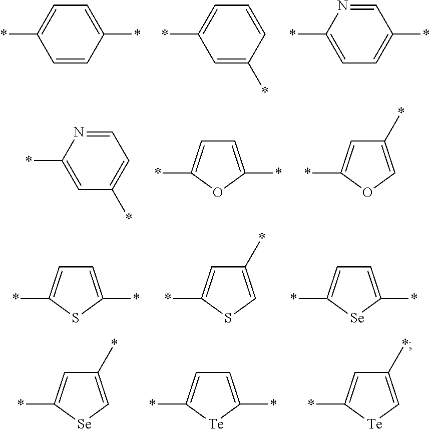

each m is an integer from 0 to 10; and

each n is an integer from 0 to 10.

In one embodiment, with reference to one or more of the embodiments above, the non-fullerene acceptor has one of the following structures:

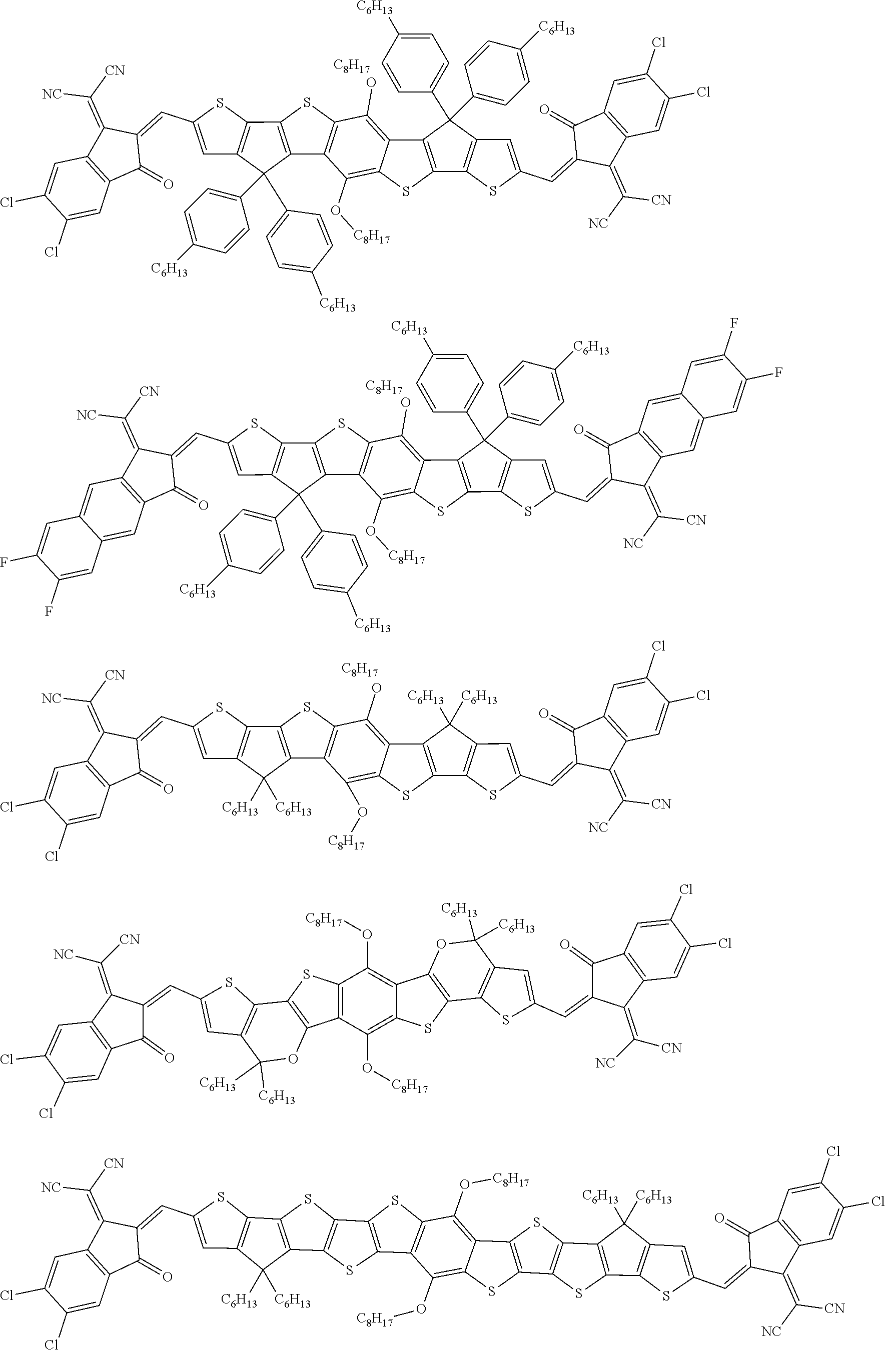

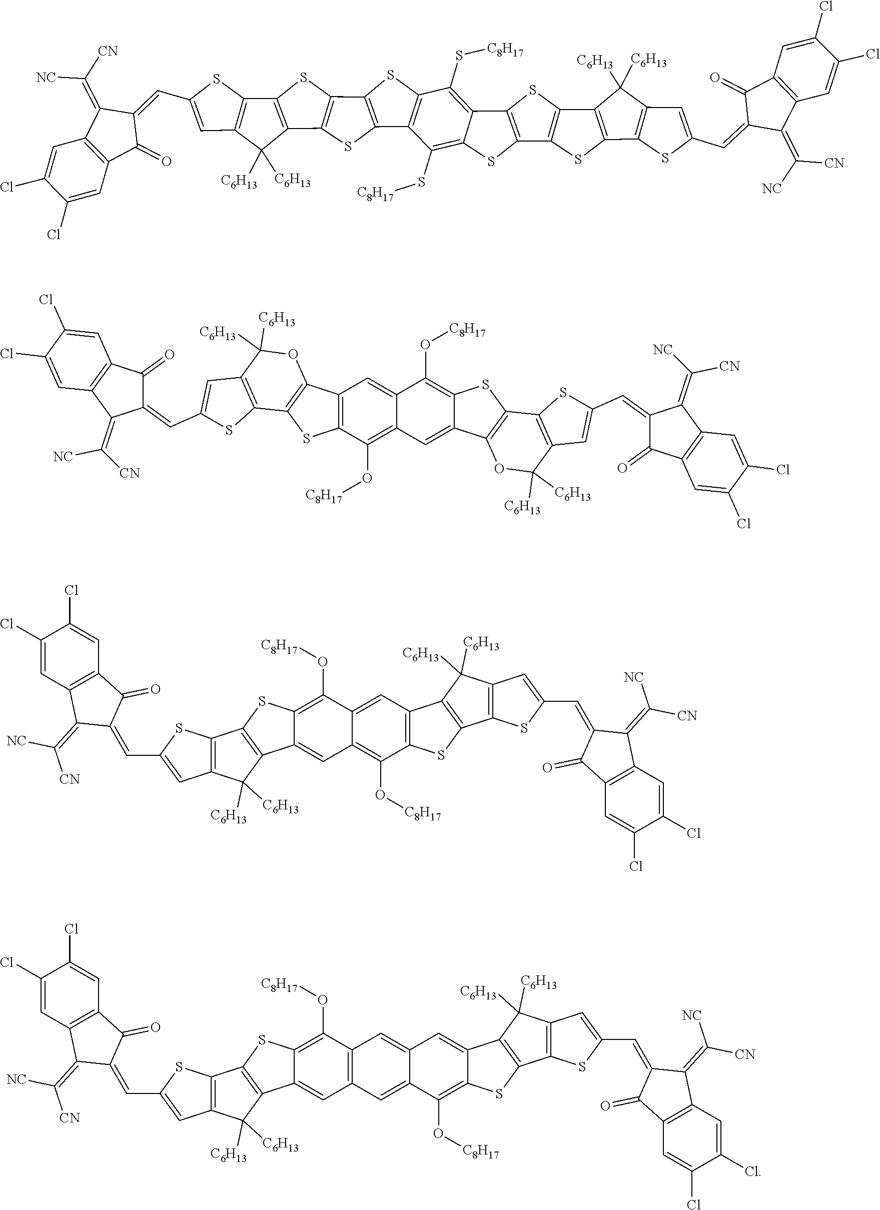

In one embodiment, with reference to one or more of the embodiments above, the non-fullerene acceptor has the following structure:

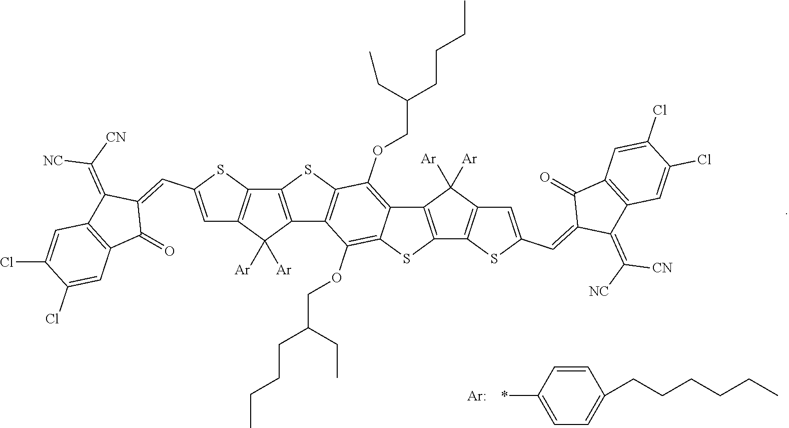

In one embodiment, with reference to one or more of the embodiments above, the first active layer has a thickness of at least 100 nm.

In one embodiment, with reference to one or more of the embodiments above, the first active layer has a thickness in a range of 150-180 nm.

In one embodiment, with reference to one or more of the embodiments above, the solar cell further includes a first buffer layer positioned between the anode and the first active layer; and a second buffer layer positioned between the second active layer and the cathode.

In one embodiment, with reference to one or more of the embodiments above, the first buffer layer and the second buffer layer are individually metal oxides selected from the group consisting of MoO₃, V₂O₅, ZnO, or TiO₂.

In one embodiment, with reference to one or more of the embodiments above, the first buffer layer or the second buffer layer comprises one or more of the following molecules:

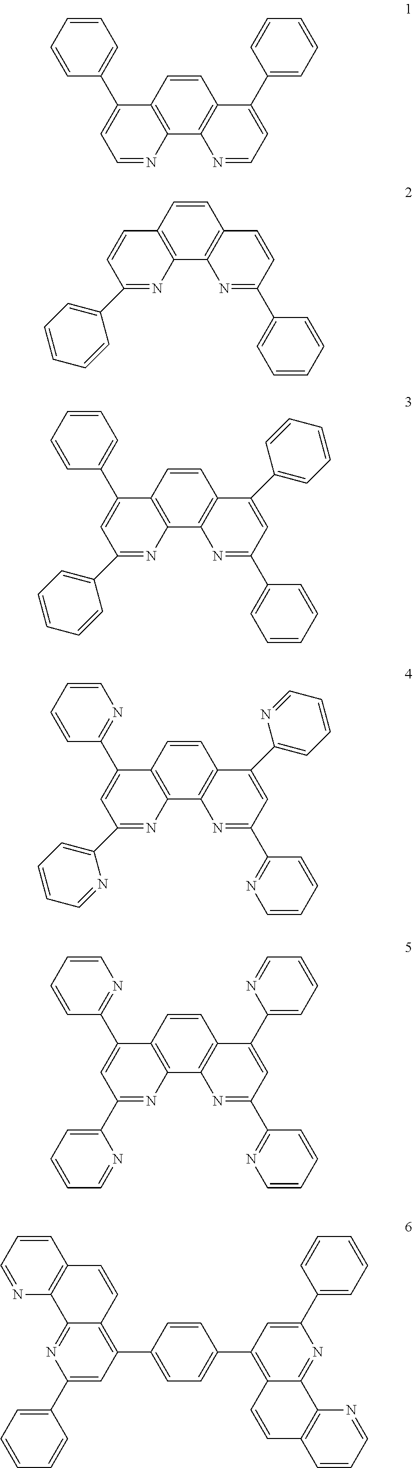

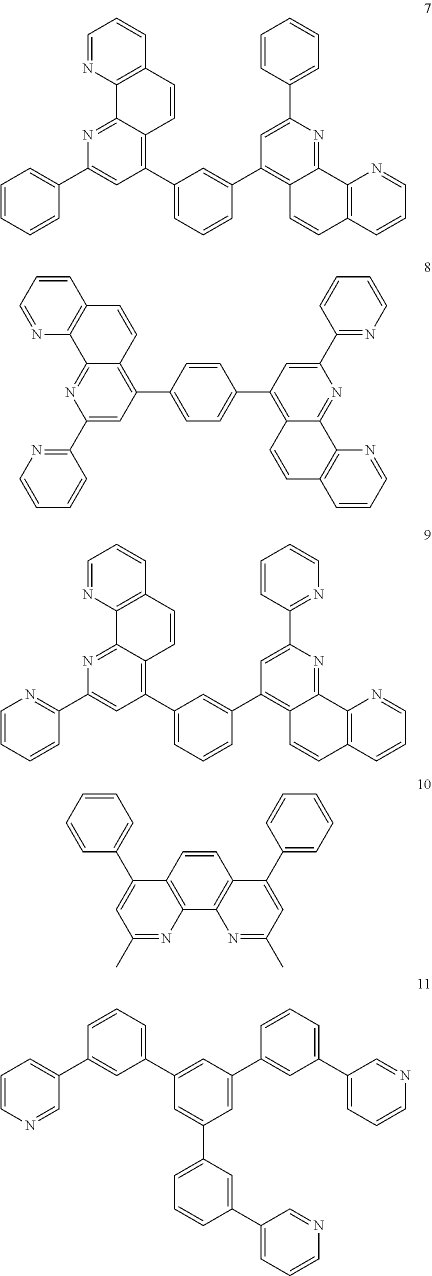

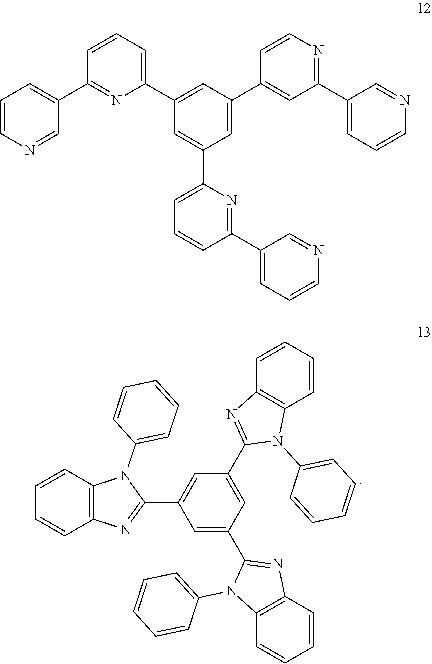

In one embodiment, with reference to one or more of the embodiments above, the second buffer layer comprises 1,3,5-tri[(3-pyridyl)-phen-3-yl]benzene.

In one embodiment, with reference to one or more of the embodiments above, the recombination zone comprises a plurality of layers configured to provide a hydrophilic-hydrophobic interface to prevent solvent penetration from the second active layer into the first active layer.

In one embodiment, with reference to one or more of the embodiments above, the recombination zone comprises a first layer having a polymer mixture of ionomers.

In one embodiment, with reference to one or more of the embodiments above, the polymer mixture comprises a sulfonated polystyrene and a polythiophene.

In one embodiment, with reference to one or more of the embodiments above, the sulfonated polystyrene is a sodium polystyrene sulfonate, and wherein the polythiophene is poly(3,4-ethylenedioxythiophene).

In one embodiment, with reference to one or more of the embodiments above, the first layer of the recombination zone has a thickness in a range of 1-100 nm.

In one embodiment, with reference to one or more of the embodiments above, the second active layer is spin coated on the first layer of the recombination zone.

In one embodiment, with reference to one or more of the embodiments above, the recombination zone comprises a second layer, and the polymer mixture of the first layer of the recombination zone is spin coated on the second layer of the recombination zone.

In one embodiment, with reference to one or more of the embodiments above, the second layer of the recombination zone comprises metal nanoparticles.

In one embodiment, with reference to one or more of the embodiments above, the metal nanoparticles comprise Ag, Au, Pd, Pt, Ti, V, Zn, Sn, Al, Co, Ni, Cu, Cr, or combinations thereof.

In one embodiment, with reference to one or more of the embodiments above, the second layer of the recombination zone has a thickness in a range of 0.1-10 Angstroms.

In one embodiment, with reference to one or more of the embodiments above, the recombination zone comprises a third layer, and the second layer of the recombination zone is positioned between the first layer of the recombination zone and the third layer of the recombination zone.

In one embodiment, with reference to one or more of the embodiments above, the third layer of the recombination zone comprises a mixture of a phenanthroline and a fullerene.

In one embodiment, with reference to one or more of the embodiments above, the phenanthroline is bathophenanthroline.

In one embodiment, with reference to one or more of the embodiments above, the fullerene is C₆₀ or C₇₀.

In one embodiment, with reference to one or more of the embodiments above, a ratio of the mixture of phenanthroline and fullerene is in a range from 1:2 to 2:1.

In one embodiment, with reference to one or more of the embodiments above, the third layer of the recombination zone has a thickness in a range of 0.1-20 nm.

In one embodiment, with reference to one or more of the embodiments above, the anode and/or the cathode is a conductive metal oxide, a metal layer, or a conducting polymer.

In one embodiment, with reference to one or more of the embodiments above, the anode is the conductive metal oxide selected from the group consisting of indium tin oxide, tin oxide, gallium indium tin oxide, zinc oxide, or zinc indium tin oxide.

In one embodiment, with reference to one or more of the embodiments above, the anode is the metal layer selected from the group consisting of Ag, Au, Pd, Pt, Ti, V, Zn, Sn, Al, Co, Ni, Cu, Cr, or combinations thereof.

In one embodiment, with reference to one or more of the embodiments above, the cathode is the conductive metal oxide selected from the group consisting of indium tin oxide, tin oxide, gallium indium tin oxide, zinc oxide, or zinc indium tin oxide.

In one embodiment, with reference to one or more of the embodiments above, the cathode is the metal layer selected from the group consisting of Ag, Au, Pd, Pt, Ti, V, Zn, Sn, Al, Co, Ni, Cu, Cr, or combinations thereof.

In one embodiment, with reference to one or more of the embodiments above, the solar cell further includes an anti-reflective coating positioned on an exterior surface of the anode.

In one embodiment, with reference to one or more of the embodiments above, the solar cell further includes an anti-reflective coating positioned on an exterior surface of the cathode.

In one embodiment, with reference to one or more of the embodiments above, the anti-reflective coating comprises a plurality of layers with alternating layers of contrasting refractive index.

In one embodiment, with reference to one or more of the embodiments above, the plurality of layers comprises a first layer having magnesium fluoride and a second layer having silicon oxide.

In one embodiment, with reference to one or more of the embodiments above, the anti-reflective coating has a thickness in a range of 10-500 nm.

In one embodiment, with reference to one or more of the embodiments above, the solar cell has a power conversion efficiency of at least 12%, or at least 14.3%, or in a range of 14-15%.

In one embodiment, with reference to one or more of the embodiments above, the solar cell has an open circuit voltage of at least 1.5 Volts, or in a range of 1.5-2.0 Volts.

In one embodiment, with reference to one or more of the embodiments above, the solar cell has a fill factor of at least 70%, or in a range of 70-75%.

In one embodiment, with reference to one or more of the embodiments above, the solar cell has a short circuit current in a range of 10-15 mA/cm², or in range of 12-13 mA/cm².

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### DESCRIPTION OF THE DRAWING FIGURES

For a more complete understanding of the disclosure, reference is made to the following detailed description and accompanying drawing figures, in which like reference numerals may be used to identify like elements in the figures.

FIG. 1A depicts an example a single junction organic photovoltaic cell.

FIG. 1B depicts an example a tandem or multi junction organic photovoltaic cell.

FIG. 1C depicts an example of a recombination zone of a multi junction organic photovoltaic cell.

FIG. 2A depicts example compounds within active layer materials in a tandem or multi-junction OPV, specifically donors (DTDCPB and PCE-10) and acceptors (C₇₀ and BT-CIC).

FIG. 2B depicts absorption coefficients of 1:2 DTDCPB:C₇₀ and 1:1.5 PCE-10:BT-CIC blended films.

FIG. 3 depicts current density-voltage (J-V) characteristics of single junction DTDCPB:C₇₀ cells with and without the charge recombination zone. Structures for the OPV cells are depicted in the inset.

FIG. 4 depicts a schematic of a tandem device showing layer thicknesses and compositions (left), and simulated absorbed optical power distribution (right), with the recombination zone highlighted by the red dashed box.

FIG. 5 depicts a tandem cell energy level diagram for the structure in FIG. 4.

FIG. 6A depicts a tandem cell performance, where the symbols and lines depict measured and simulated external quantum efficiencies (EQEs), respectively, of the tandem and discrete sub-cells. The measured EQEs are for the discrete single junctions, while the simulations are for the sub-cells in the stack.

FIG. 6B depicts current density-voltage characteristics of the optimized tandem cell together with the single junction sub-cells.

FIG. 7 depicts an efficiency histogram for a population of 36 optimized tandem cells (2 mm² effective area, without anti-reflection coatings). The inset in FIG. 7 depicts a tandem yield for populations of 2 mm² and 9 mm² devices.

FIG. 8A depicts SEM and cross-section views of the m (porous) deposited on the Si substrate with an 85° oblique angle.

FIG. 8B depicts the measured transmission ratio between glass substrates with the anti-reflective coating (ARC).

FIG. 8C depicts the J-V characteristics of tandem cells with and without ARC.

FIG. 9A depicts the quantum efficiency of DTDCPB:C₇₀ front cell, as measured by National Renewable Energy Laboratory (NREL).

FIG. 9B depicts the quantum efficiency of PCE-10:BT-CIC back cell, as measured by NREL.

FIG. 10 depicts measured tandem cell current-voltage characteristics (2 mm² device with ARC), with the extracted efficiency of 14.7±0.3%.

FIG. 11A depicts the fill factor of sub-cells and tandems cells as functions of DTDCPB:C₇₀ (160 nm) blend ratios. The measured and calculated values are shown with solid and open symbols, respectively.

FIG. 11B depicts the fill factor versus light intensity for DTDCPB:C₇₀ and PCE-10:BT-CIC single junction cells. The error bars for the measured (±0.01) and the calculated (±0.02) data are omitted for clarity.

While the disclosed devices and systems are representative of embodiments in various forms, specific embodiments are illustrated in the drawings (and are hereafter described), with the understanding that the disclosure is intended to be illustrative, and is not intended to limit the claim scope to the specific embodiments described and illustrated herein.

### DETAILED DESCRIPTION

Various non-limiting examples of OPVs and compositions within various layers of an OPV are described in greater detail below.

### Definitions

As used herein, the terms “electrode” and “contact” may refer to a layer that provides a medium for delivering photo-generated current to an external circuit or providing a bias current or voltage to the device. That is, an electrode, or contact, provides the interface between the active regions of an organic photosensitive optoelectronic device and a wire, lead, trace or other means for transporting the charge carriers to or from the external circuit. Examples of electrodes include anodes and cathodes, which may be used in a photosensitive optoelectronic device.

As used herein, the term “transparent” may refer to an electrode that permits at least 50% of the incident electromagnetic radiation in relevant wavelengths to be transmitted through it. In a photosensitive optoelectronic device, it may be desirable to allow the maximum amount of ambient electromagnetic radiation from the device exterior to be admitted to the photoconductive active interior region. That is, the electromagnetic radiation must reach a photoconductive layer(s), where it can be converted to electricity by photoconductive absorption. This often dictates that at least one of the electrical contacts should be minimally absorbing and minimally reflecting of the incident electromagnetic radiation. In some cases, such a contact should be transparent or at least semi-transparent.

As used herein, the term “semi-transparent” may refer to an electrode that permits some, but less than 50% transmission of ambient electromagnetic radiation in relevant wavelengths. The opposing electrode may be a reflective material so that light which has passed through the cell without being absorbed is reflected back through the cell.

As used and depicted herein, a “layer” refers to a member or component of a photosensitive device whose primary dimension is X-Y, i.e., along its length and width. It should be understood that the term layer is not necessarily limited to single layers or sheets of materials. In addition, it should be understood that the surfaces of certain layers, including the interface(s) of such layers with other material(s) or layers(s), may be imperfect, wherein said surfaces represent an interpenetrating, entangled or convoluted network with other material(s) or layer(s). Similarly, it should also be understood that a layer may be discontinuous, such that the continuity of said layer along the X-Y dimension may be disturbed or otherwise interrupted by other layer(s) or material(s).

As used herein, a “photoactive region” refers to a region of the device that absorbs electromagnetic radiation to generate excitons. Similarly, a layer is “photoactive” if it absorbs electromagnetic radiation to generate excitons. The excitons may dissociate into an electron and a hole in order to generate an electrical current.

As used herein, the terms “donor” and “acceptor” refer to the relative positions of the highest occupied molecular orbital (“HOMO”) and lowest unoccupied molecular orbital (“LUMO”) energy levels of two contacting but different organic materials. If the LUMO energy level of one material in contact with another is lower, then that material is an acceptor. Otherwise it is a donor. It is energetically favorable, in the absence of an external bias, for electrons at a donor-acceptor junction to move into the acceptor material, and for holes to move into the donor material.

As used herein, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Because ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, the term “band gap” (E_{g}) of a polymer may refer to the energy difference between the HOMO and the LUMO. The band gap is typically reported in electronvolts (eV). The band gap may be measured from the UV-vis spectroscopy or cyclic voltammetry. A “low band gap” polymer may refer to a polymer with a band gap below 2 eV, e.g., the polymer absorbs light with wavelengths longer than 620 nm.

As used herein, the term “excitation binding energy” (E_{B}) may refer to the following formula: E_{B}=(M⁺+M⁻)−(M*+M), where M⁺ and M⁻ are the total energy of a positively and negatively charged molecule, respectively; M* and M are the molecular energy at the first singlet state (Si) and ground state, respectively. Excitation binding energy of acceptor or donor molecules affects the energy offset needed for efficient exciton dissociation. In certain examples, the escape yield of a hole increases as the HOMO offset increases. A decrease of exciton binding energy E_{B} for the acceptor molecule leads to an increase of hole escape yield for the same HOMO offset between donor and acceptor molecules.

As used herein, “power conversion efficiency” (PCE) (η_{ρ}) may be expressed as:

$${η}_{ρ} = \frac{{V}_{OC} * F F * {J}_{SC}}{{P}_{O}}$$

wherein V_{OC} is the open circuit voltage, FF is the fill factor, J_{SC} is the short circuit current, and P_{O} is the input optical power.

As used herein, “spin coating” may refer to the process of solution depositing a layer or film of one material (i.e., the coating material) on a surface of an adjacent substrate or layer of material. The spin coating process may include applying a small amount of the coating material on the center of the substrate, which is either spinning at low speed or not spinning at all. The substrate is then rotated at high speed in order to spread the coating material by centrifugal force. Rotation is continued while the fluid spins off the edges of the substrate, until the desired thickness of the film is achieved. The applied solvent is usually volatile, and simultaneously evaporates. Therefore, the higher the angular speed of spinning, the thinner the film. The thickness of the film also depends on the viscosity and concentration of the solution and the solvent.

Organic Photovoltaic Cells

As disclosed herein, the various compositions or molecules may be provided within a single junction solar cell or a tandem or multi junction solar or organic photovoltaic (OPV) cell. As supported by the Example section below, the various compositions or molecules for a solar cell disclosed herein may be advantageous in providing one or more improvements over conventionally known solar cells. Specifically, the various solar cell layers and molecules may provide an improved power conversion efficiency over conventionally known solar cells.

As disclosed herein, the improved solar cells may include one or more of the following: (1) at least two active layers having different wavelength absorptions (e.g., visible and near-infrared light), (2) at least two active layers including a vacuum thermal evaporation (VTE) front cell and a solution-processed/spin coated back cell, (3) a recombination zone or layer positioned between adjacent active layers of a multi junction solar cell, (4) a cathode buffer layer, (5) spin coating an active layer on a surface of the recombination zone, (6) an anti-reflective coating (ARC) positioned on an exterior surface of an electrode of the solar cell, or (7) an active layer having a thickness of greater than 100 nm. These embodiments, along with additional embodiments of the improved solar cell compositions are discussed in greater detail below.

Solar Cell Overview

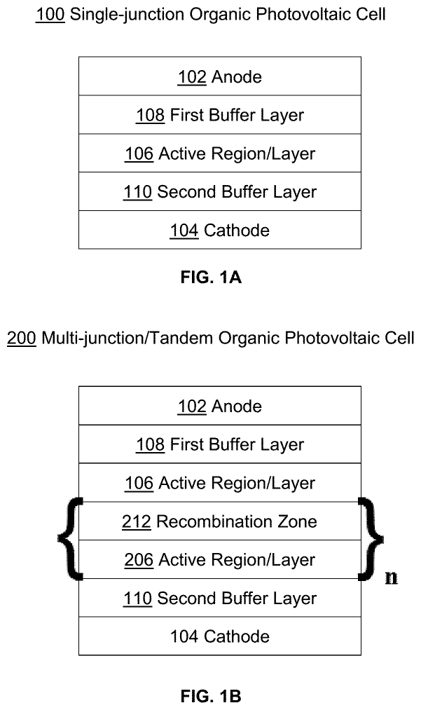

FIG. 1A depicts an example of various layers of a single junction solar cell or OPV 100. The OPV cell may include two electrodes having an anode 102 and a cathode 104 in superposed relation, at least one donor composition, and at least one acceptor composition, wherein the donor-acceptor material or active layer 106 is positioned between the two electrodes 102, 104. At least one buffer layer 108 may be positioned between the anode 102 and the active layer 106. Additionally, or alternatively, at least one buffer layer 110 may be positioned between the active layer 106 and cathode 104.

FIG. 1B depicts an example of various layers of a tandem or multi junction solar cell or organic photovoltaic cell (OPV) 200. The OPV cell may include two electrodes having an anode 102 and a cathode 104 in superposed relation, at least one donor composition, and at least one acceptor composition positioned within a plurality of active layers or regions 106, 206 between the two electrodes 102, 104. Additionally, an interconnecting layer or recombination zone 212 is positioned between adjacent active layers 106, 206.

While only two active layers or regions 106, 206 are depicted in FIG. 1B, additional active layers or regions are also possible. For example, n may be any positive integer (e.g., 1, 2, 3, 4, etc.) When n is a positive integer greater than 1, the composition of the additional recombination zone and active layer may be a same or different composition as the composition of the recombination zone 212 and active layer 206 depicted in FIG. 1B.

Non-limiting examples of the various compositions of the various layers of the single-junction or multi junction OPVs are described herein.

Anode

The anode 102 may include a conducting oxide, thin metal layer, or conducting polymer. In some examples, the anode 102 includes a (e.g., transparent) conductive metal oxide such as indium tin oxide (ITO), tin oxide (TO), gallium indium tin oxide (GITO), zinc oxide (ZO), or zinc indium tin oxide (ZITO). In other examples, the anode 102 includes a thin metal layer, wherein the metal is selected from the group consisting of Ag, Au, Pd, Pt, Ti, V, Zn, Sn, Al, Co, Ni, Cu, Cr, or combinations thereof. In yet other examples, the anode 102 includes a (e.g., transparent) conductive polymer such as polyanaline (PANI), or 3,4-polyethyl-enedioxythiophene:polystyrenesulfonate (PEDOT:PSS).

The thickness of the anode 102 may be 0.1-1000 nm, 1-10 nm, 0.1-10 nm, 10-100 nm, or 100-1000 nm.

In some examples, an anti-reflective coating (ARC) may be positioned on an exterior surface of the anode 102. This may be advantageous in further improving the power conversion efficiency (PCE) of the solar cell. In some examples, the PCE may be improved by 1-10% or about 5% with the addition of the ARC (e.g., improving the PCE from approximately 14% to 15%).

The ARC may include a plurality of layers with alternating layers of contrasting refractive index. The plurality of layers of the ARC may include a first layer having magnesium fluoride and a second layer having silicon oxide. In some examples, the ARC has a thickness in a range of 1-1000 nm, 10-500 nm, 100-500 nm, or 100-200 nm.

Cathode

The cathode 104 may be a conducting oxide, thin metal layer, or conducting polymer similar or different from the materials discussed above for the anode 102. In certain examples, the cathode 104 may include a metal or metal alloy. The cathode 104 may include Ca, Al, Mg, Ti, W, Ag, Au, or another appropriate metal, or an alloy thereof.

The thickness of the cathode 104 may be 0.1-1000 nm, 1-10 nm, 0.1-10 nm, 10-100 nm, or 100-1000 nm.

In some examples, an anti-reflective coating may be positioned on an exterior surface of the cathode 104. As noted above, the ARC may be advantageous in improving the overall PCE of the solar cell. The ARC may include a plurality of layers with alternating layers of contrasting refractive index. The plurality of layers of the ARC may include a first layer having magnesium fluoride and a second layer having silicon oxide. In some examples, the ARC has a thickness in a range of 1-1000 nm, 10-500 nm, 100-500 nm, or 100-200 nm.

Buffer Layers

As noted above, the OPV may include one or more charge collecting/transporting buffer layers positioned between an electrode 102, 104 and the active region or layer 106. The buffer layer(s) is advantageous in protecting the adjacently positioned layers or compositions from adversely interacting with each other. Additionally, certain compositions within the buffer layer may be advantageous in further improving the power conversion efficiency (PCE) of the solar cell.

The first and second buffer layers 108, 110 may individually be a metal oxide. In certain examples, the first and second buffer layers 108, 110 may individually include one or more of MoO₃, V₂O₅, ZnO, or TiO₂. In some examples, the first buffer layer 108 has a similar composition as the second buffer layer 110. In other examples, the first and second buffer layers 108, 110 have different compositions.

The first and/or second buffer layers 108, 110 may include vacuum-deposited electron transporting compositions or molecules.

In some examples, the first and/or second buffer layers 108, 110 are selected from the group consisting of:

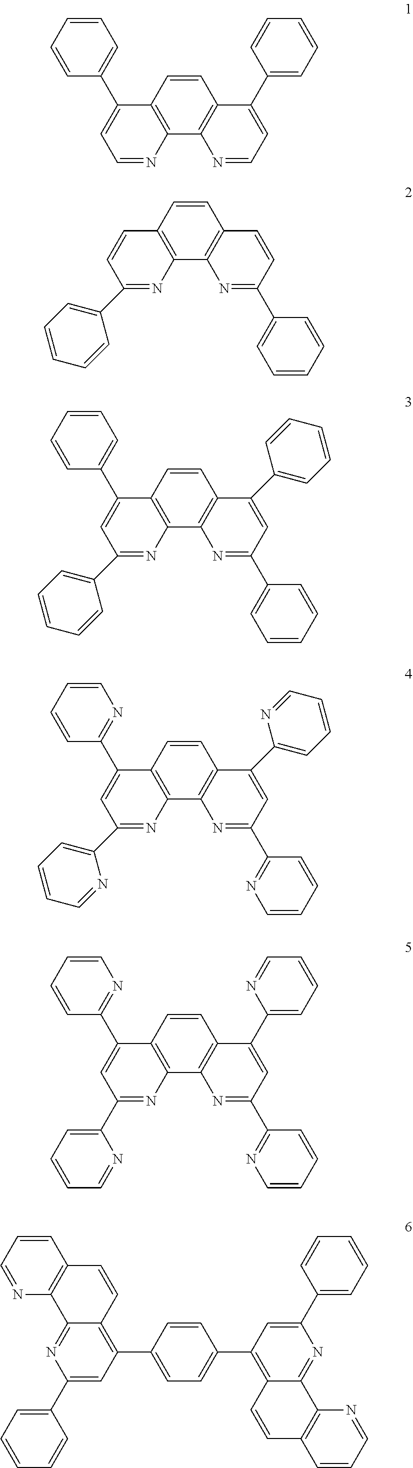

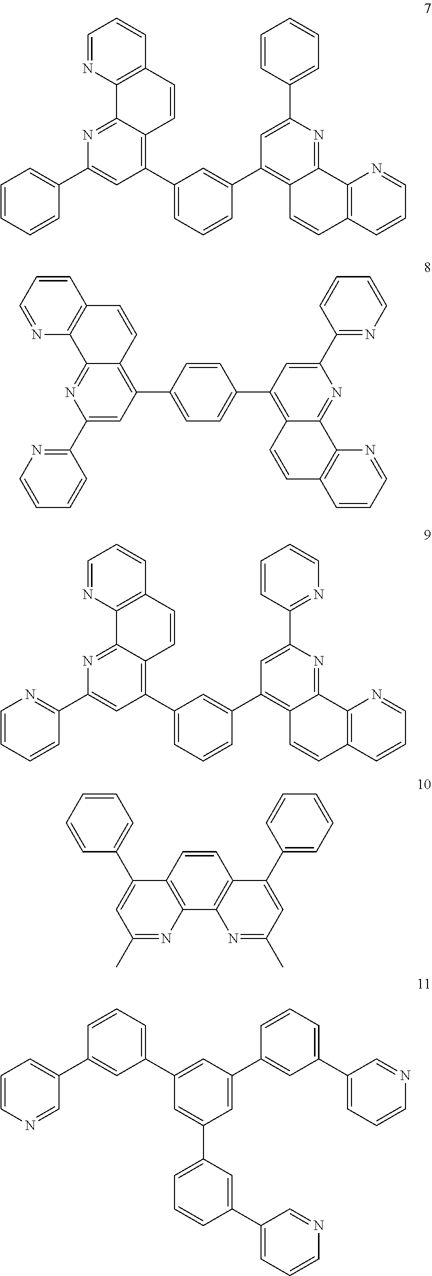

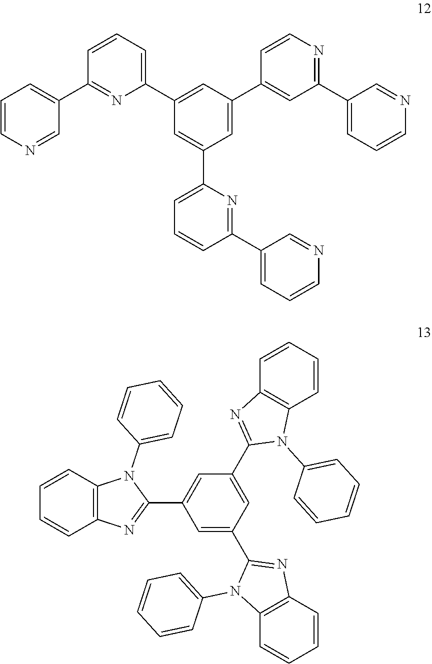

In some examples, the first and/or second buffer layers 108, 110 include 1,3,5-tri[(3-pyridyl)-phen-3-yl]benzene (herein referred to as “TmPyPB”), or a derivative thereof. In one specific example, the buffer layer adjacent to the cathode, (i.e., the cathode buffer layer 110) includes TmPyPB.

In other examples, the first and/or second buffer layers 108, 110 include one or more of the following: 3,3′,5,5′-Tetra[(m-pyridyl)-phen-3-yl]biphenyl; 1,3-Bis[3,5-di(pyridin-3-yl)phenyl]benzene; 1,3,5-Tri(p-pyrid-3-yl-phenyl)benzene; or 2,4,6-Tris(3′-(pyridin-3-yl)biphenyl-3-yl)-1,3,5-triazine.

The thickness of each buffer layer 108, 110 may be 0.1-100 nm, 0.1-50 nm, 1-10 nm, 0.1-10 nm, or 10-100 nm.

Active Layers

As noted above, in a single junction solar cell, a single active layer 106 is present. In a multi junction cell, two or more active layers 106, 206 are present. In the multi junction cell, the composition of each active layer may be a same or different from each additional active layer.

In certain examples, the first active layer in the multi junction cell includes a composition configured to absorb light in a first wavelength spectrum, while the second active layer includes a composition configured to absorb light in a second, different wavelength spectrum.

The first active layer may be positioned between the anode and the recombination zone, and the second active layer may be positioned between the cathode and the recombination zone. In such an arrangement, the first active layer may be referred to as a “front cell,” and the second active layer may be referred to as a “back cell.”

The first wavelength spectrum of the first active layer may include at least a portion of a visible light spectrum. For example, the first wavelength spectrum may have a wavelength range of 380-750 nm, 400-750 nm, 400-700 nm, 380-700 nm, 380-600 nm, 400-600 nm, 500-750 nm, 500-700 nm, or 500-600 nm. The second wavelength spectrum of the second active layer may include at least a portion of a near-infrared light spectrum. For example, the second wavelength spectrum may have a wavelength range of 500-1000 nm, 600-1000 nm, 700-1000 nm, 800-1000 nm, 900-1000 nm, 500-900 nm, 600-900 nm, 700-900 nm, 800-900 nm, 500-800 nm, 600-800 nm, or 700-800 nm.

In alternative embodiments, the first active layer may include at least a portion of a near infrared spectrum and the second active layer may include at least a portion of the visible light spectrum.

In certain examples, the first wavelength spectrum is adjacent to the second wavelength spectrum (e.g., first wavelength spectrum=400-700 nm, and second wavelength spectrum=700-900 nm). In other examples, the first wavelength spectrum overlaps with the second wavelength spectrum (e.g., first wavelength spectrum=400-700 nm, and second wavelength spectrum=600-900 nm).

In some additional examples, the solar cell includes n active layers (e.g., 3, 4, 5, etc.) positioned between the anode and cathode (wherein additional recombination zones re positioned between adjacent active layers). Each additional active layer is configured to absorb light in an n^{th} (e.g., third, fourth, fifth, and so on) wavelength spectrum.

The thickness of each active layer in the single junction or multi junction solar cell is variable. In certain examples, the thickness of the active layer 106 in a single junction cell may be less than 100 nm, or in a range of 10-100 nm, 50-100 nm, or 60-90 nm.

In a multi junction solar cell, the thickness of the first active layer 106 or front cell may be at least 100 nm, at least 150 nm, or in a range of 10-200 nm, 50-100 nm, 100-200 nm, 100-150 nm, 150-200 nm, 150-180 nm, 125-175 nm, or 140-160 nm. The thickness of the second active layer 206 or back cell may be less than 100 nm, or in a range of 10-100 nm, 50-100 nm, or 60-90 nm.

In some examples, the first active layer 106 or front cell may be formed by vacuum thermal evaporation (VTE). Alternatively, or additionally, the second active layer 206 or back cell may be formed from a solution and solvent (e.g., solution-processed, wherein the solvent in the back-cell mixture evaporates during the formation of the cell). In such a solution process, the back cell may be spin coated on top of an external surface of the intermediate layer or recombination zone 212, wherein the solvent evaporates.

The active regions or layers 106, 206 positioned between the electrodes includes a composition or molecule having an acceptor and a donor. The composition may be arranged as an acceptor-donor-acceptor (A-D-A) or donor-acceptor-acceptor (d-a-a′).

Various examples of donor and acceptor compositions for each individual active layer are discussed in greater detail below.

Donor Composition of Active Layer

In certain examples, the donor material or composition within the active layer or region 106, 206 is a low energy band gap polymer composition. For example, the donor composition is a polymer having a band gap of less than 2 eV.

One non-limiting example of low band gap polymer donor is poly[4,8-bis(5-(2-ethylhexyl)thiophen-2-yl)benzo[1,2-b:4,5-bi]dithiophene-co-3-fluorothieno[3,4-b]thio-phene-2-carboxylate, or a derivative thereof. Another example of a low band gap polymer donor is poly[4,8-bis(5-(2-ethylhexyl)thiophen-2-yl)benzo[1,2-b; 4,5-b]dithiophene-2,6-diyl-alt-(4-(2-ethylhexyl)-3-fluorothieno[3,4-b]thiophene+2-carboxylate-2-6-diyl)] (herein referred to as “PCE-10”), or a derivative thereof.

In another example, the donor is 2-[(7-{44N,N-Bis(4-methylphenyl)amino]phenyl}-2,1,3-benzothiadiazol-4-yl)methylene]propanedinitrile (herein referred to as “DTDCPB”), or a derivative thereof.

Other non-limiting examples of low band gap polymer donors include the compounds depicted below in P1-P9, and their derivatives:

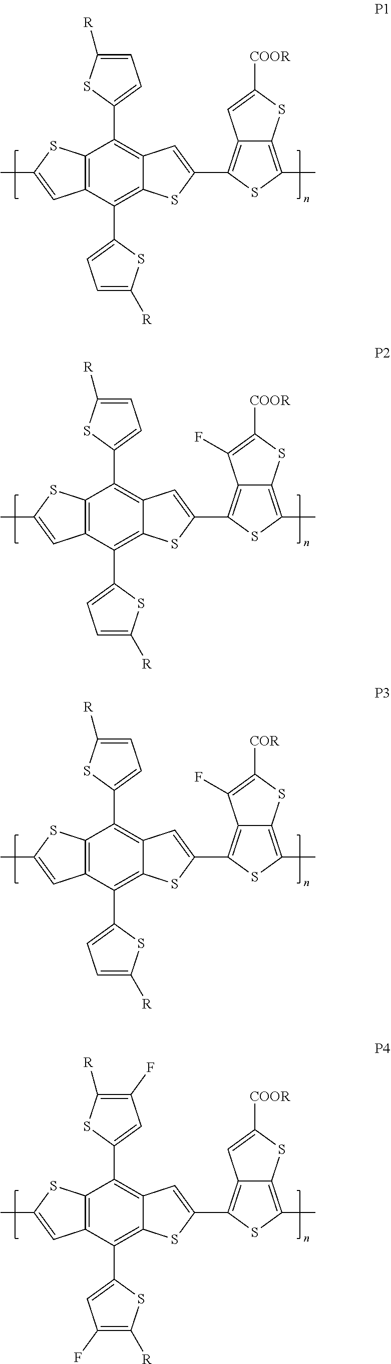

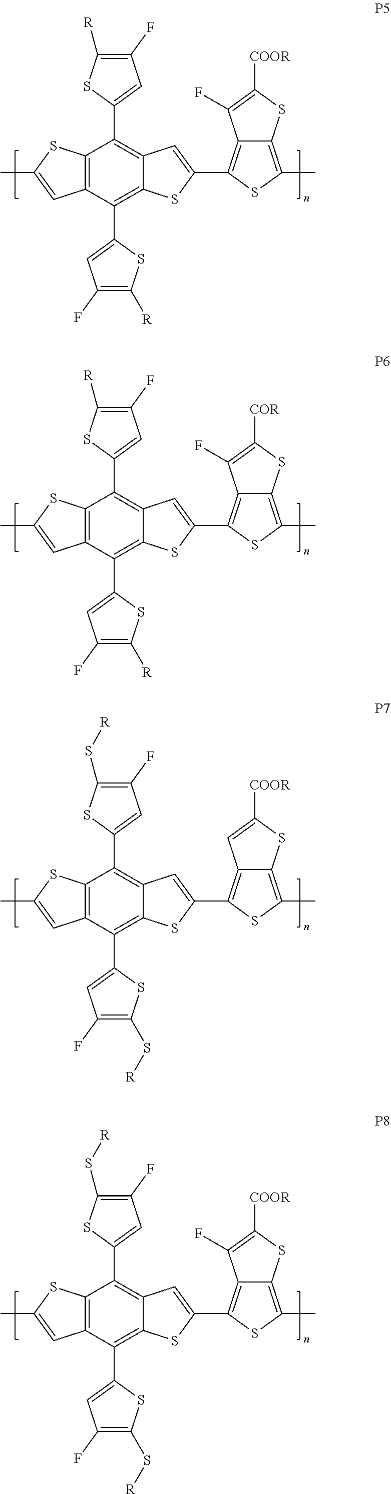

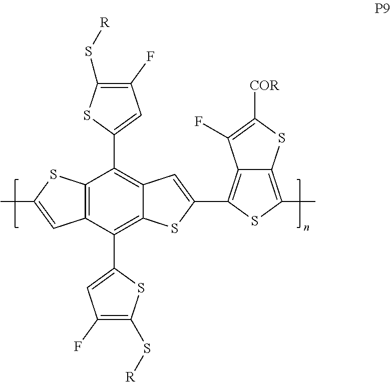

In the polymers depicted in P1-P9, n refers to the degree of polymerization. In some examples, n is within a range of 1-1000, 1-100, or 10-1000.

Additionally, R may represent a linear or branched saturated or unsaturated non-aromatic hydrocarbon, e.g., within the C₂-C₂₀ range. In certain examples, R represents a saturated hydrocarbon or alkyl group. Examples of linear or branched alkyl groups in the C₂-C₂₀ range include methyl, ethyl, n-propyl, isopropyl, isobutyl, π-butyl, sec-butyl, tert-butyl, isopentyl, π-pentyl, neopentyl, π-hexyl, and 2-ethylhexyl. In one particular example, R represents 2-ethylhexyl.

Acceptor Composition

The acceptor in the active layers or materials 106, 206 may be a fullerene or non-fullerene acceptor molecule or composition. A fullerene molecule includes a hollow sphere, ellipsoid, or tube shape. The fullerene acceptor may be a spherical C₂₀, or C₂ₙ molecule, wherein n is an integer within a range of 12-100, for example. In certain examples, the fullerene acceptor is C₆₀ or C₇₀, or a derivative thereof.

In certain examples, the first active layer or front cell (e.g., active cell closest to the anode) of a multi junction solar cell may include a fullerene molecule or composition (e.g., C₆₀ or C₇₀). As noted above, such a first active layer or front cell may be grown as a thin film with the fullerene molecule via a vacuum thermal evaporation (VTE) process.

Alternatively, the acceptor is a non-fullerene molecule. In such an example, the structure of the acceptor composition does not form a hollow sphere, ellipsoid, or tube. In certain examples, the second active layer or back cell (e.g., active cell closest to the cathode) of the multi junction cell may include the non-fullerene molecule. As noted above, the second active layer or back cell having the non-fullerene acceptor may be spin coated on top of an external surface of the intermediate layer or recombination zone 212. The process may involve forming a solution having the non-fullerene acceptor and a solvent, wherein during the spin coating process, the solvent evaporates.

In certain examples, the non-fullerene acceptor composition is a compound having one of the following three structures (I, II, or III):

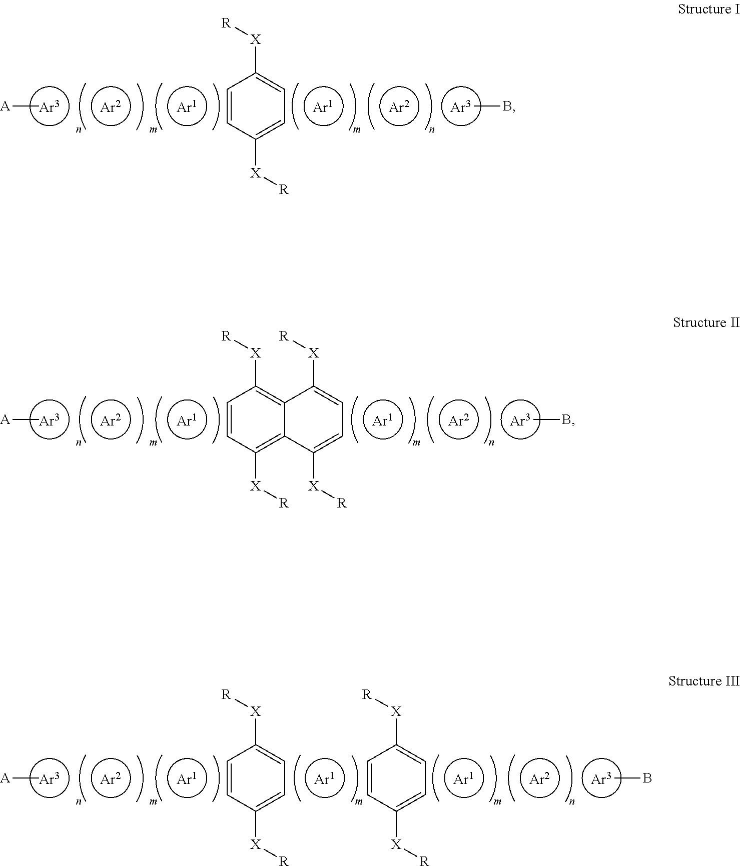

In these structures, Ar¹, Ar², and Ar³ individually represent aromatic groups. The aromatic groups may be 5- or 6-membered cyclic rings. The cyclic rings may also be heterocyclic rings, wherein one carbon has been replaced by a non-carbon atom. In certain examples, the non-carbon atom within the heterocyclic ring may be nitrogen or a chalcogen such as oxygen, sulfur, selenium, or tellurium.

Ar¹ may include an aromatic group which is conjugated fused connected to a benzene ring in the compound. Each Ar¹ may be individually selected from the group consisting of:

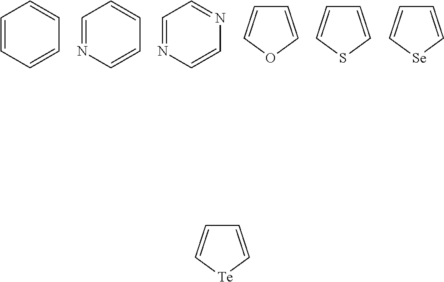

Ar² may include an aromatic group which is conjugated fused connected to a Ar¹ ring in the compound. Each Ar² may be individually selected from the group consisting of:

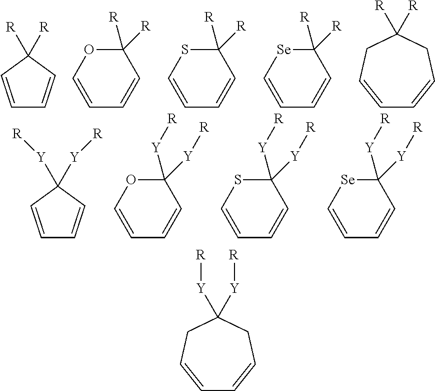

Ar³ may include an aromatic group which is conjugated fused connected to a Ar² ring in the compound. Each Ar³ may be individually selected from the group consisting of:

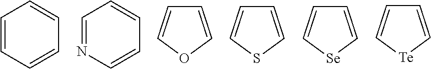

As noted in structures I, II, and III, the aromatic groups Ar¹ and Ar² may be repeated (or may not present at all). For example, each m may be an integer from 0 to 10, from 0 to 5, from 0 to 3, from 1 to 3, from 1 to 2, or 1; and each n may be an integer from 0 to 10, from 0 to 5, from 0 to 3, from 1 to 3, from 1 to 2, or 1. In certain examples, the aromatic groups Ar¹, Ar², and Ar³, in combination with benzene ring(s) within the non-fullerene acceptor may provide a coplanar ring structure having a conjugation length of seven to fifteen rings. In other terms, the overall length of the non-fullerene acceptor may be at least 20 angstroms, 25 angstroms, 30 angstroms, 35 angstroms, 40 angstroms, 50 angstroms, or between 20-50 angstroms, 25-40 angstroms, or 25-35 angstroms.

Each X substituent may individually be selected from the group consisting of: oxygen, carbon, hydrogen, sulfur, selenium, and nitrogen.

Y may include an aryl group or an aromatic hydrocarbon. For example, Y may include benzene attached to a R substituent (e.g., a hydrocarbon chain at the para position). Alternatively, Y may include a five-membered cyclic ring attached to a R substituent (e.g., a hydrocarbon chain), wherein one carbon atom of the cyclic ring has been replaced by a chalcogen such as oxygen, sulfur, selenium, or tellurium.

Each Y substituent may individually be selected from the group consisting of:

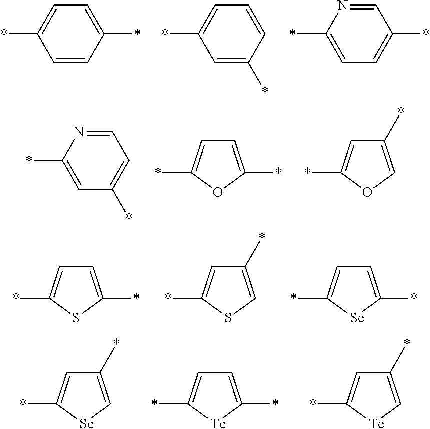

In certain examples, Y in combination with the R substituent provides a substituent selected from the group consisting of:

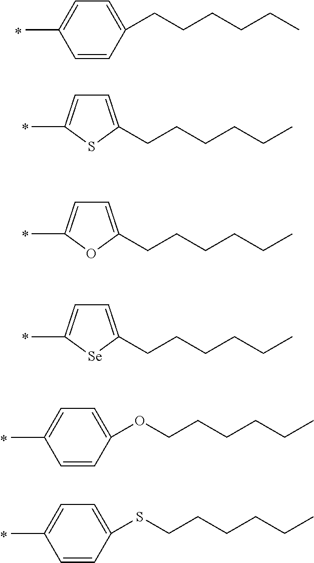

Each R substituent (attached to X or Y within the non-fullerene acceptor compounds) may individually be a linear or branched saturated or unsaturated non-aromatic hydrocarbon in the C₁-C₂₀ range. Non-limiting examples include methyl, ethyl, π-propyl, isopropyl, isobutyl, π-butyl, sec-butyl, tert-butyl, isopentyl, π-pentyl, neopentyl, π-hexyl, and 2-ethylhexyl. In one particular example, R represents 2-ethylhexyl.

In some examples, the R substituent may be a substituted hydrocarbon wherein the carbon at the 1-position is replaced with oxygen or sulfur, for example.

Alternatively, R includes an unsaturated 5- or 6-membered ring (substituted or not-substituted) (e.g., thiophene or benzene) attached to a hydrocarbon (e.g., at the para position of benzene). In some examples, R includes an aryl group or an aromatic hydrocarbon.

In certain examples, R is selected from the group consisting of:

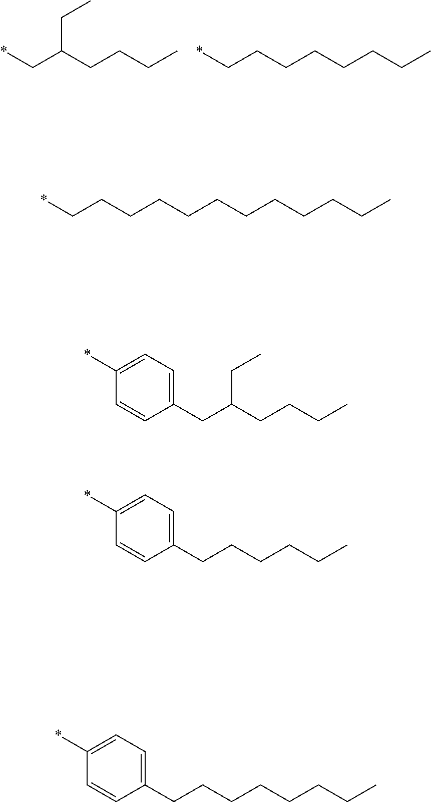

The A or B substituent that bookends the compound may individually be selected from the group consisting of:

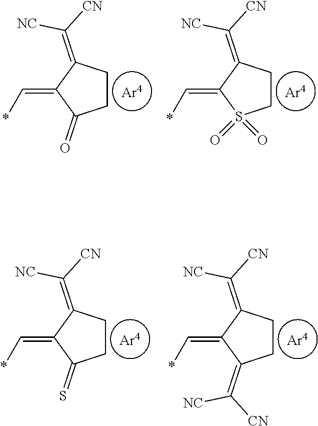

Ar⁴ within the A or B substituent is an aromatic group, which is conjugated fused to the adjacent ring. In certain examples, Ar⁴ is an aromatic group having at least one halogen (e.g., fluorine, chlorine, bromine, iodine, or astatine) substituent attached to the aromatic ring. In some examples, Ar⁴ is an aromatic group selected from the group consisting of:

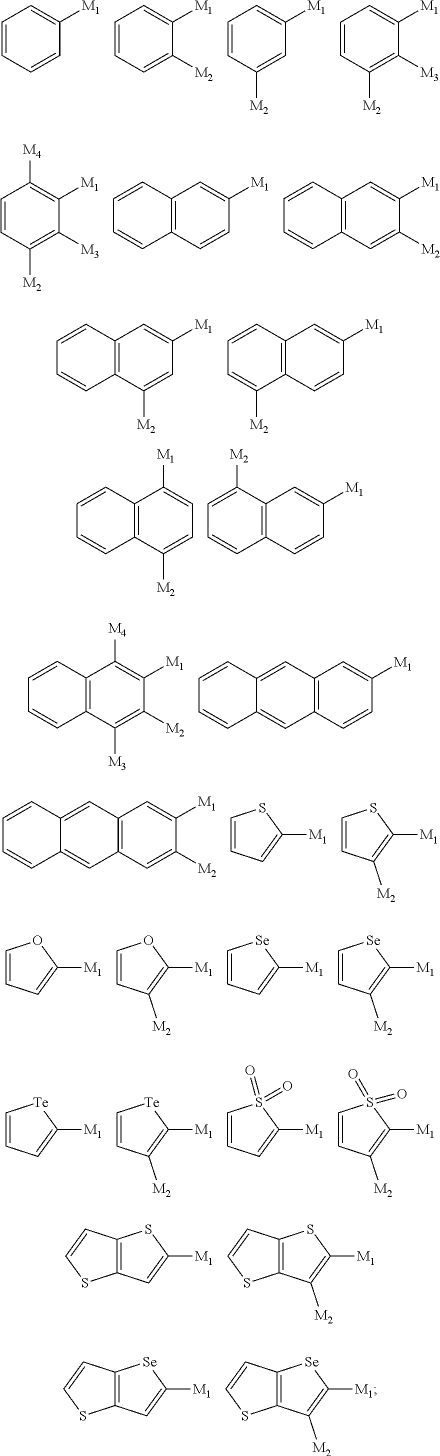

In the possible substituents for A or B, M₁-M₄ may individually be selected from the group consisting of hydrogen, fluorine, chlorine, bromine, iodine, astatine, and cyano groups. In certain examples, at least one M substituent is a halogen (e.g., fluorine, chlorine, bromine, iodine, or astatine). In other examples, each M substituent is a halogen. In certain examples, at least one M substituent is chlorine. In other examples, each M substituent is chlorine.

The electron-withdrawing halogen (e.g., Cl) atoms are advantageous as they effectively lower the energy gap by enhancing the intramolecular charge transfer and delocalization of π-electrons into the unoccupied, atomic 3d orbitals. Moreover, the intermolecular interactions of Cl—S and Cl—Cl result in ordered molecular stacks in the donor-acceptor blend films.

Non-limiting examples of the coplanar ring structures contained within the non-fullerene acceptor are provided in compounds C1-C11 below.

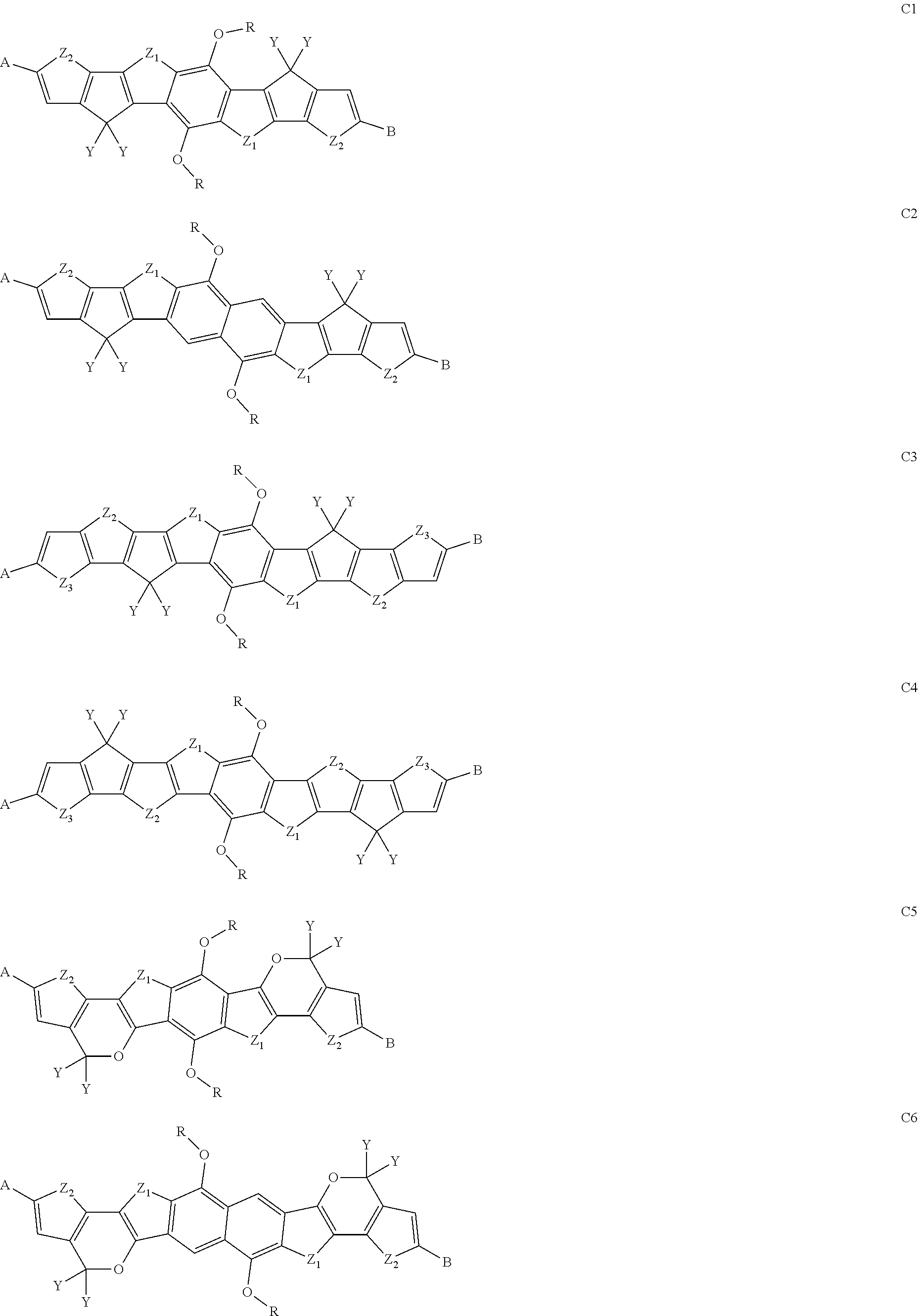

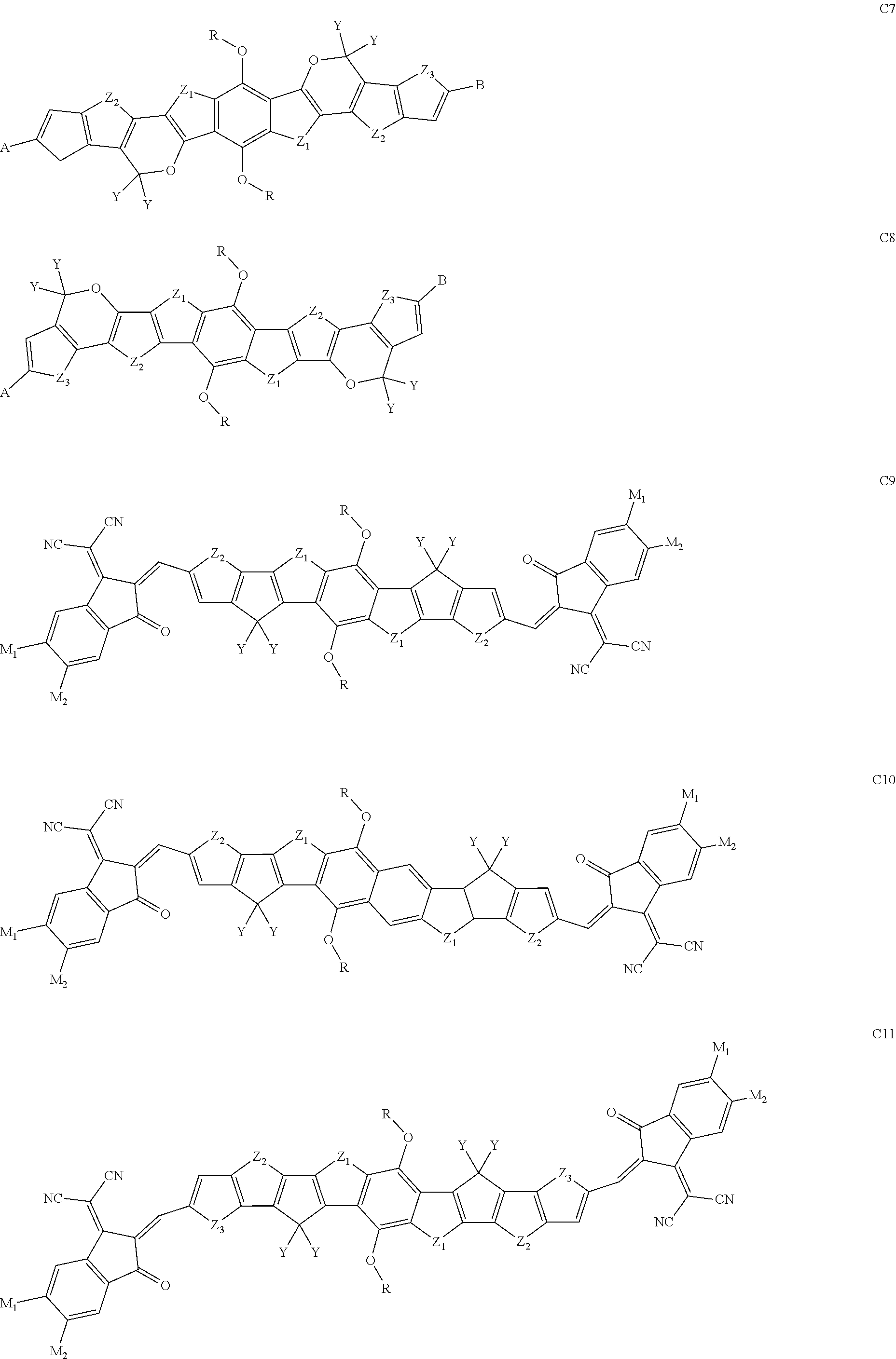

Z₁, Z₂, and Z₃ may be individually selected from the group consisting of hydrogen and chalcogens (e.g., oxygen, sulfur, selenium, or tellurium). In certain examples, Z₁, Z₂, and Z₃ may be individually selected from the group consisting of oxygen, sulfur, selenium, or tellurium.

In certain examples, Z₁, Z₂, and Z₃ may be selected from one of the following:

| Example | Z₁ | Z₂ | Z₃ |
|---|---|---|---|
| 1 | S | S | S |
| 2 | S | O | S |
| 3 | S | O | O |
| 4 | O | O | O |
| 5 | O | O | S |
| 6 | O | S | S |
| 7 | Se | S | S |
| 8 | Se | Se | S |
| 9 | Se | Se | Se |
| 10 | Se | S | O |
| 11 | Se | O | O |
| 12 | Se | S | Se |

Non-limiting examples of the non-fullerene acceptor (structure I) include:

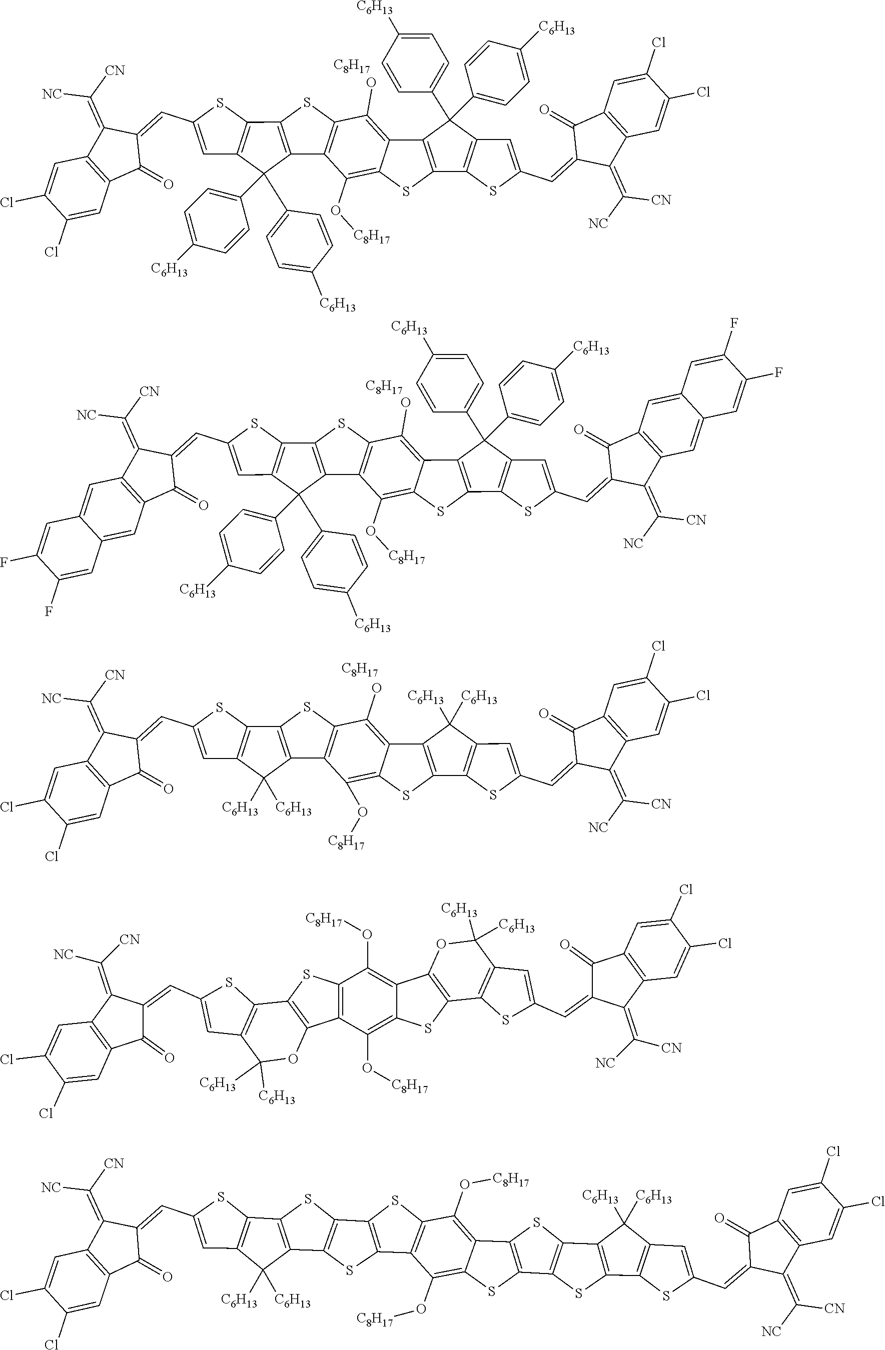

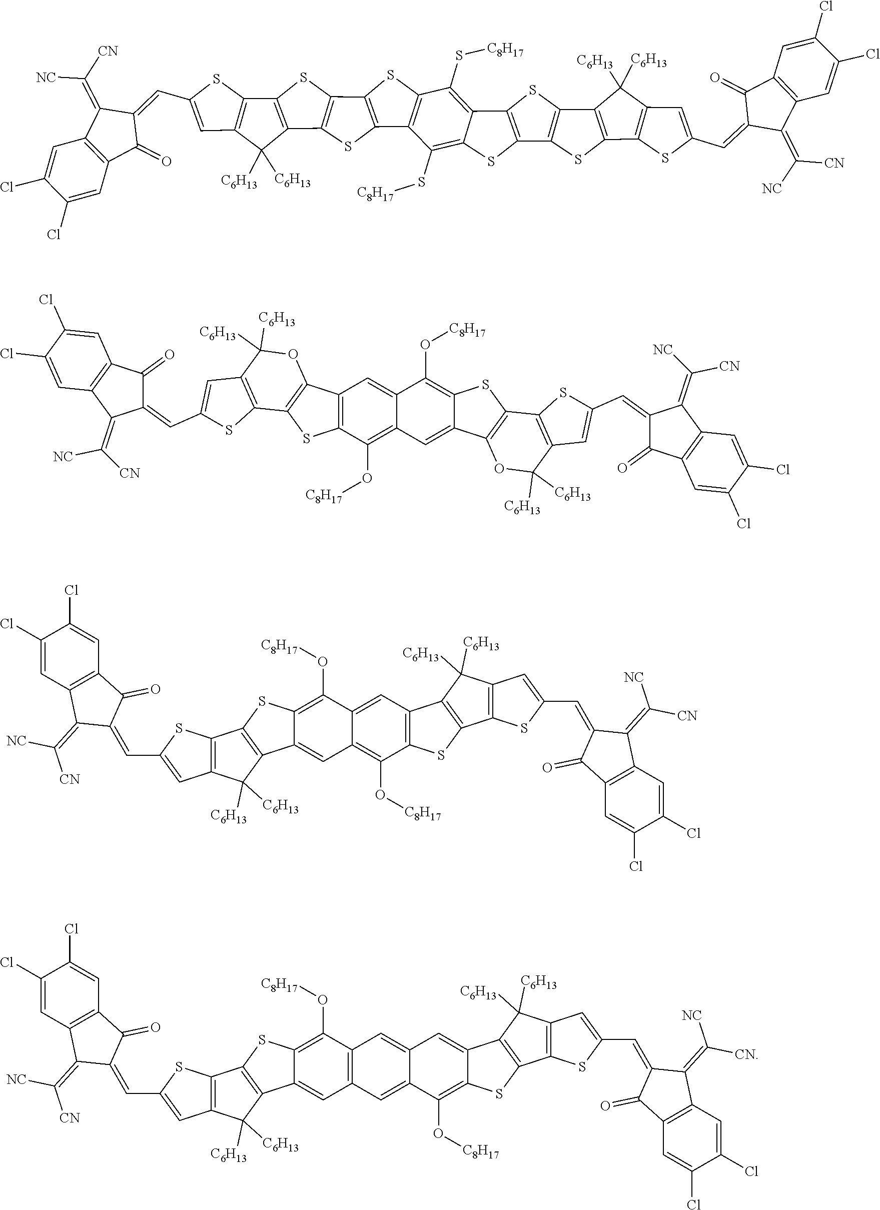

Non-limiting examples of the non-fullerene acceptor (structure II) include:

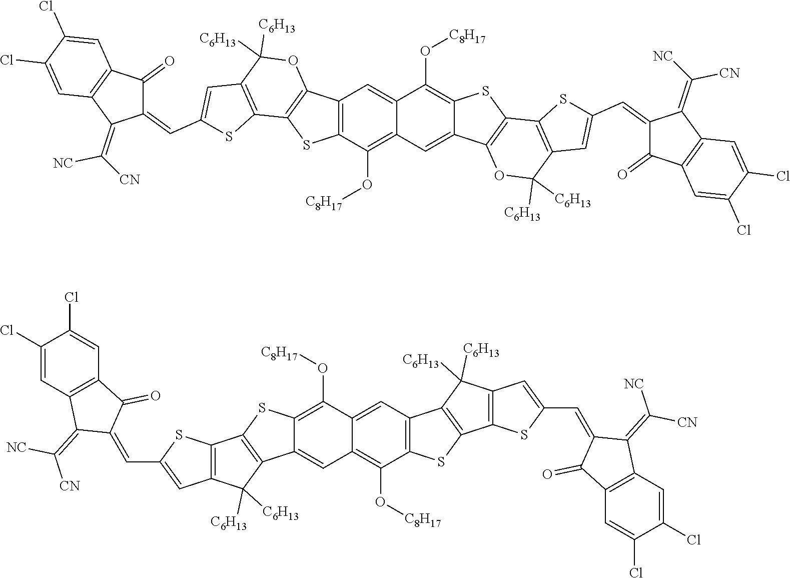

Non-limiting examples of the non-fullerene acceptor (structure III) include:

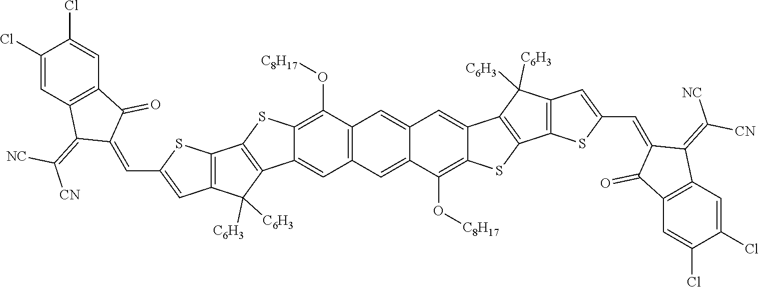

In one particular example, the non-fullerene acceptor is (4,4,10,10-tetrakis(4-hexylphenyl)-5,11-(2-ethylhexyloxy)-4,10-dihydro-dithienyl[1,2-b:4,5b]benzodi-thiophene-2,8-diyl)bis(2-(3-oxo-2,3-dihydroinden-1-ylidene)malononitrile) (herein referred to as “BT-IC”). BT-IC has planar structure with a small torsion angle <1° and consequently, a high electron mobility. However, the absorption of BT-IC does not extend to wavelengths λ>850 nm. This leaves an unused part of the solar spectrum and a potential opening for further improvement in solar cell performance.

In another example, the non-fullerene acceptor is (4,4,10,10-tetrakis(4-hexylphenyl)-5,11-(2-ethylhexyloxy)-4,10-dihydro-dithienyl[1,2-b:4,5b]benzodi-thiophene-2,8-diyl) bis(2-(3-oxo-2,3-dihydroinden-5,6-dichloro-1-ylidene) malononitrile (depicted in the structure below, herein referred to as “BT-CIC”). This structure provides a narrow absorption band confined to the near-infrared spectrum through the introduction of high electron affinity halogen atoms (e.g., chlorine atoms).

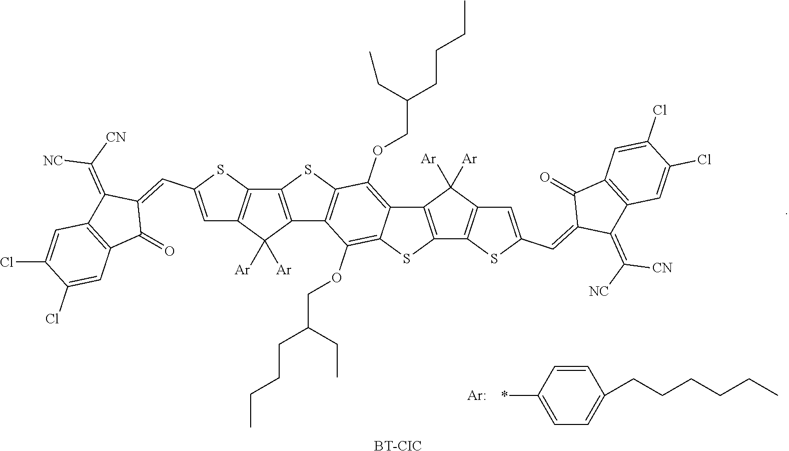

In this example, four chlorine atoms are positioned in the 5,6-positions of the 2-(3-oxo-2,3-dihydroinden-1-ylidene) malononitrile. The design is advantageous as it avoids significant issues of previously reported in chlorinated molecules with non-specific atomic site positioning (and hence property variability).

Such non-fullerene acceptor compositions disclosed herein provide certain improved characteristics over conventional acceptor compositions. For example, the NFAs disclosed herein may provide an increased electron density for the donor molecule; a reduced electron density for the acceptor molecule, and an increased conjugation length of the A-D-A molecule.

The electron-withdrawing halogen (e.g., Cl) atoms effectively lower the energy gap by enhancing the intramolecular charge transfer and delocalization of π-electrons into the unoccupied, atomic 3d orbitals. Moreover, the intermolecular interactions of Cl—S and Cl—Cl result in ordered molecular stacks in the donor-acceptor blend films.

In certain examples, the length of the non-fullerene acceptor may be at least 20 angstroms, 25 angstroms, 30 angstroms, 35 angstroms, 40 angstroms, 50 angstroms, or between 20-50 angstroms, 25-40 angstroms, or 25-35 angstroms.

Interconnecting Layer/Recombination Zone

In a multi junction solar cell, at least one intermediate layer or recombination zone may be positioned between adjacent active layers. In other words, as depicted in FIG. 1B, a recombination zone 212 is positioned between the first active layer 106 and the second active layer 206. To the extent additional active layers are present, a corresponding recombination zone may be positioned between each pair of adjacent active layers.

The recombination zone may include one layer or a plurality of layers configured to protect the adjacent active layers from interfering with one another. Specifically, the recombination zone may be configured to prevent a solvent within an active layer (e.g., the second active layer 206) from penetrating and damaging the adjacent active layer (e.g., the first active layer 106). In some examples, the recombination zone may include a hydrophilic-hydrophobic interface to prevent solvent penetration from one active layer into the other active layer. In other words, the combination of layers (as described below) within the recombination zone 212, may prevent solvent penetration and provide a device yield that is greater than 90%, 95%, 99%, 99.5%, or 99.9%. As such, the presence of a recombination or intermediate zone between active layers of a multi junction cell may be advantageous in providing a power cell with an improved power conversion efficiency (PCE) without adversely affecting the open circuit voltage (V_{oc}).

FIG. 1C depicts a recombination zone 212 of a multi junction cell 200. The recombination zone 212 is positioned between a front cell or first active layer 106 and a back cell or second active layer 206. The recombination zone 212 includes a plurality of layers.

A first layer 222 of the recombination zone 212 may be positioned adjacent to the back cell. In some examples, the back cell or second active layer 206 may be spin coated onto the external surface of the first layer 222. The process of spin coating one layer onto another, as defined above, may be advantageous in balancing the current in the solar cell.

The first layer 222 may function as a hole transporting layer of the adjacent active layer (e.g., the back cell). In some examples, the first layer 222 may include a polymer mixture of ionomers. The polymer mixture may include a sulfonated polystyrene and/or a polythiophene. In certain examples, the sulfonated polystyrene is a sodium polystyrene sulfonate, and the polythiophene is poly(3,4-ethylenedioxythiophene).

The first layer 222 of the recombination zone 212 may have a thickness in a range of 0.1-100 nm, 1-100 nm, 50-100 nm, 1-50 nm, 10-50 nm or 25-75 nm.

The recombination zone 212 may include a second layer 224 positioned adjacent to the first layer 222. In some examples, the first layer 222 of the recombination zone may be spin coated onto a surface of the second layer 224.

The intermediate or second layer 224 of the recombination zone 212 may include metal nanoparticles (e.g., particles having an average size, length, or diameter in a range of 0.1-10 nm). The metal nanoparticles may include metals selected from the group consisting of Ag, Au, Pd, Pt, Ti, V, Zn, Sn, Al, Co, Ni, Cu, Cr, or combinations thereof. In one particular example, the metal nanoparticles include Ag metal nanoparticles.

The second layer 224 of the recombination zone 212 may have a thickness in a range of 0.1-100 Angstroms, 0.1-10 Angstroms, 1-10 Angstroms, 1-5 Angstroms, or 1-3 Angstroms.

The recombination zone 212 may include a third layer 226 positioned adjacent to the second layer 224, such that the second layer 224 is positioned between the first layer 222 and the third layer 226. The third layer 226 may be positioned adjacent to the front cell or first active layer 106 of the solar cell. As such, the third layer 226 may act as an electron transporting buffer layer between the first active layer 106 and additional layers of the recombination zone 212.

The third layer 226 of the recombination zone 212 may include a phenanthroline, a fullerene, or a mixture thereof. In some additional examples, the third layer 226 of the recombination zone 212 may include a buffer molecule selected from the group consisting of:

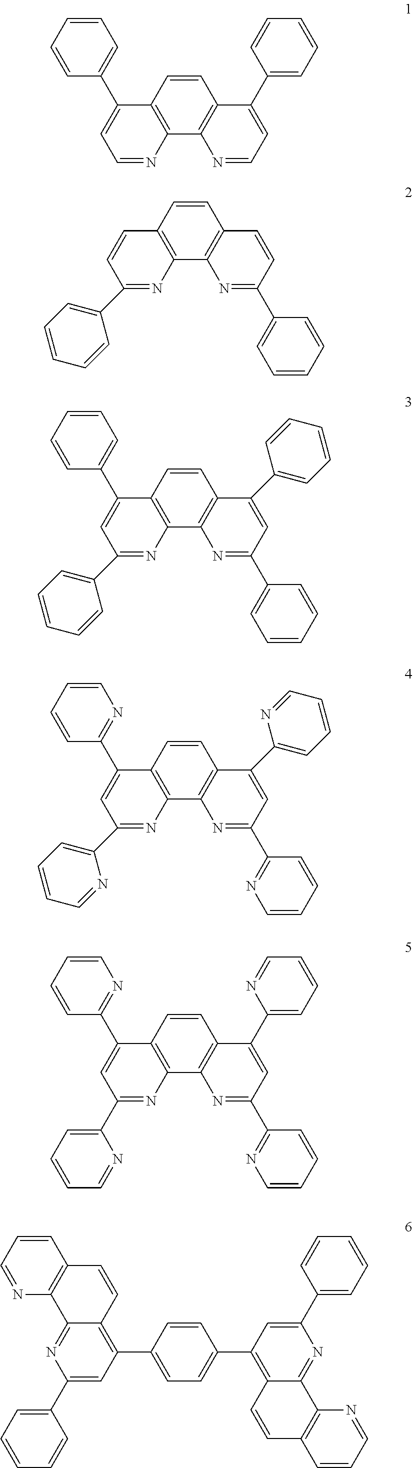

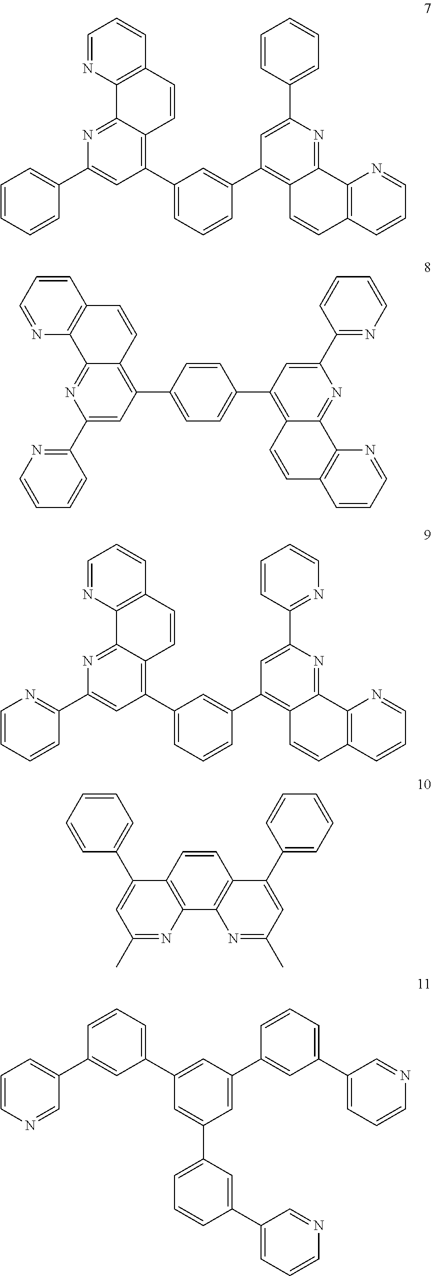

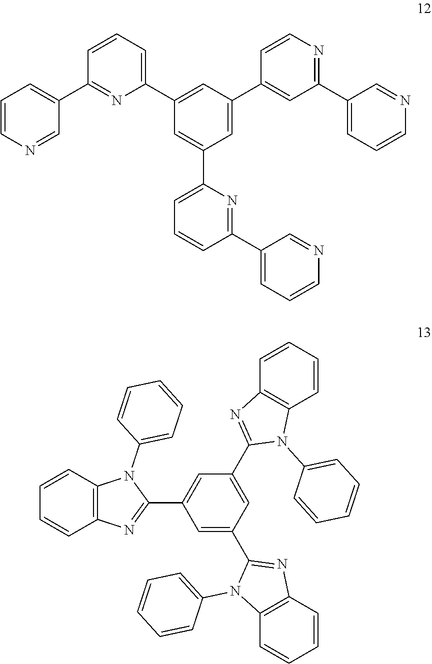

In some examples, the third layer 226 of the recombination zone 212 may include 1,3,5-tri[(3-pyridyl)-phen-3-yl]benzene (“TmPyPB”), or a derivative thereof.

In some examples, the phenanthroline in the third layer 226 is bathophenanthroline. In certain examples, the fullerene is a spherical C₂₀, or C₂ₙ molecule, wherein n is an integer within a range of 12-100, for example. In certain examples, the fullerene acceptor is C₆₀ or C₇₀, or a derivative thereof.

In some examples, the third layer 226 is a mixture of the phenanthroline and fullerene (e.g., a mixture of bathophenanthroline and C₆₀). The ratio of the mixture of the phenanthroline and fullerene may be in a range from 1:10 to 10:1, 1:5 to 5:1, 1:2 to 2:1, or 1:1.

The third layer 226 of the recombination zone 212 may have a thickness in a range of 0.01-100 nm, 0.1-20 nm, 1-10 nm, or 5-10 nm.

OPV Performance Characteristics

In certain examples, the single junction or multi junction cell may have certain improved performance properties. For example, the solar cells disclosed herein may include an improved power conversion efficiency (PCE). In certain examples, the solar cell may have a PCE of at least 10%, at least 11%, at least 12%, at least 13%, at least 14%, at least 14.3%, or at least 15%. In some examples, the multi junction solar cells disclosed herein have PCEs in a range of 10-15%, 12-15%, 14-15%, 14.3-15%, or 14.7-15.3%.

The solar cells disclosed herein may have a high open circuit voltage (V_{oc}). The V_{oc} may be at least 1 V, at least 1.1 V, at least 1.2 V, at least 1.3 V, at least 1.4 V, at least 1.5 V, in a range of 1.5-2 V, in a range of 1.3-1.7 V, or in a range of 1.5-1.6 V.

The solar cells disclosed herein may have an improved fill factor (FF). The FF may be at least 50%, at least 60%, at least 65%, at least 70%, at least 75%, at least 80%, in a range of 50-80%, in a range of 60-80%, in a range of 65-75%, or approximately 70%.

The solar cells disclosed herein may have a high short circuit current (J_{sc}). The J_{sc} may be in a range of 10-30 mA/cm², 10-15 mA/cm², or 12-13 mA/cm².

The solar cells disclosed herein may have an improved external quantum efficiency (EQE). The EQE may at least 50%, at least 60%, at least 65%, at least 70%, at least 75%, at least 80%, at least 85%, in a range of 65-85%, in a range of 65-75%, or approximately 70%, as measured between wavelengths of 500-850 nm and providing a transparency window between wavelengths of less than 600 nm that is filled by the visible-absorbing sub-cell in the tandem structure.

### EXAMPLES

Sub-Cell and Recombination Zone Characterization

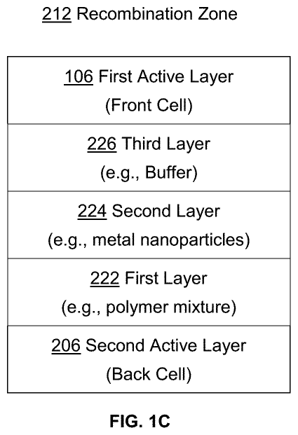

The molecular structures of the donors and acceptors are shown in FIG. 2A, with the active layer absorption coefficients in FIG. 2B. The vacuum deposited small molecule DTDCPB:C₇₀ cell strongly absorbs light between wavelengths of X=400 nm to 700 nm. Since the PCE-10:BT-CIC cell absorbs mostly between 600 and 900 nm, the combination of these cells in a tandem structure results in broad spectral coverage of solar illumination between 400 nm and 900 nm, with each sub-cell in the stack generating similar currents.

The asymmetric distribution of electron donating and withdrawing groups in the d-a-a′ DTDCPB results in ground state dipole moment of greater than 10 D that facilitates 7t-7t stacking and intermolecular charge transport. The non-fullerene acceptor, BT-CIC, has an acceptor-donor-acceptor (a-d-a) configuration whose planar backbone and electron-withdrawing Cl atoms reduces the energy gap. The non-fullerene acceptor exhibits a lowest unoccupied molecular orbital (LUMO) energy of −4.1 eV, which is similar to that of the fullerene acceptor [6,6]-phenyl-C₇₁-butyric acid methyl ester (PC71BM), but a shallower highest occupied molecular orbital (HOMO) energy of −5.5 eV (compared to −6.0 eV for PC71BM). The 1:1.5 PCE-10:BT-CIC mixture shows absorption from X=500 nm to 950 nm, with a peak absorption coefficient of 1.3×105 cm⁻¹ at around X=700 nm and 800 nm, compared with a peak of 1.0×105 cm¹ for DTDCPB:C₇₀ at X=500 nm.

The performance of the optimized single element PCE-10:BT-CIC NFA cell used for integration into the tandem cell is summarized in Table 1, with the structure: Indium tin oxide (ITO)/PEDOT:PSS (50 nm)/PCE-10:BT-CIC (1:1.5, 75 nm)/1,3,5-Tri[(3-pyridyl)-phen-3-yl]benzene (TmPyPB, 5 nm)/Ag (100 nm). It attains J_{sc}=22.1±0.4 mA/cm², V_{oc}=0.69±0.01 V and FF=0.70±0.01, resulting in PCE=10.7±0.2% at 1 sun (100 mW/cm²), AM 1.5G simulated spectral illumination. This is comparable to that of an analogous inverted cell, indicating efficient electron and hole injection from the TmPyPB and PEDOT:PSS buffer layers. The device shows an average external quantum efficiency, EQE >70% between λ=500 nm and 850 nm, while leaving a transparency window at X<600 nm that is filled by the visible-absorbing sub-cell in the tandem structure.

TABLE 1
Discrete sub-cells and tandem device performances.

| | J_{SC} | V_{OC} | | PCE |
|---|---|---|---|---|
| Device | (mA/cm²) | (V) | FF | (%) |
| [Back] PCE-10:BT-CIC | 22.1 ± 0.4 | 0.69 ± 0.01 | 0.70 ± 0.01 | 10.7 ± 0.2 |
| (1:1.5, 75 nm) | | | | |
| [Front] DTDCPB:C₇₀ | 16.2 ± 0.3 | 0.90 ± 0.01 | 0.67 ± 0.01 | 9.8 ± 0.2 |
| (1:2, 160 nm) | | | | |
| Tandem (w/160 nm | 12.6 ± 0.2 | 1.58 ± 0.01 | 0.72 ± 0.01 | 14.3 ± 0.3 |
| DTDCPB:C₇₀) | | | | |
| Tandem (w/170 nm | 12.7 ± 0.2 | 1.59 ± 0.01 | 0.71 ± 0.01 | 14.3 ± 0.3 |
| DTDCPB:C₇₀) | | | | |
| Tandem (w/170 nm | 13.3 ± 0.3 | 1.59 ± 0.01 | 0.71 ± 0.01 | 15.0 ± 0.3 |
| DTDCPB:C₇₀ + ARC) | | | | |

Due to a high J_{sc}>20 mA/cm² and the spectral coverage into the NIR of the PCE-10:BT-CIC single junction cell, it is optimally employed as the back cell in the tandem (or multi-junction) OPV. This creates a processing challenge since the PEDOT:PSS and PCE-10:BT-CIC need to be spin-coated from solution on top of the previously vacuum thermal evaporation (VTE)-grown films comprising the front cell.

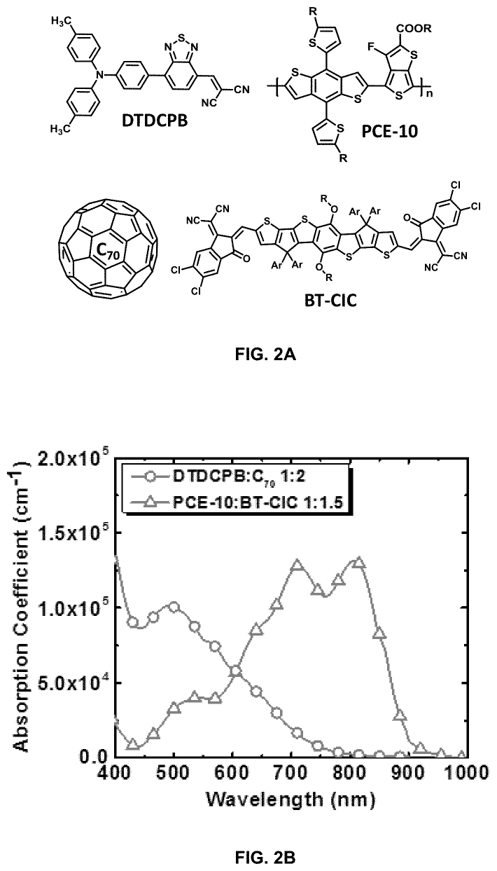

FIG. 3 depicts the VTE grown DTDCPB:C₇₀ single junction structure: ITO/MoO₃ (10 nm)/DTDCPB:C₇₀ (1:1 80 nm)/bathophenanthroline (BPhen):C₆₀ (1:1, 8 nm)/Ag (100 nm). To test the feasibility of the recombination zone, the recombination zone is inserted immediately adjacent to the Ag cathode (see FIG. 3, inset, right). The recombination zone consists of three layers: a 3 Å thick Ag nanoparticle (NP) layer that promotes electron-hole recombination deposited on the BPhen: C₆₀ mixed exciton blocking and electron conducting filter, followed by spin-coating the PEDOT:PSS protective cap. As shown by the J-V characteristics in FIG. 3, the reference DTDCPB:C₇₀ cell yields V_{oc}=0.92±0.01 V, FF=0.68±0.01 and PCE=9.1±0.2%. The device with the recombination zone (RCZ) exhibits an identical V_{oc} and FF=0.66±0.01. The lower efficiency of 7.2±0.2% primarily arises from the lower J_{sc}=11.8±0.2 mA/cm² compared to 14.6±0.3 mA/cm² for the reference cell. This is due to the non-optimal optical field distribution resulting from the insertion of the 50 nm thick PEDOT:PSS in the device with the recombination layers.

The hydrophilicity of the acidic (pH=1-2) PEDOT:PSS usually leads to incomplete wetting and the possibility of dissolving the underlying hydrophobic layers. In the tandem structure, acid-resistant BPhen: C₆₀ is employed as the front cell exciton blocking layer. The contact angle of the PEDOT:PSS on a BPhen:C₆₀ film is 97±2°, smaller than on the PCE-10:PC₇₁BM (101±2°) active layer. The ultra-thin Ag NP layer on top of BPhen:C₆₀ further decreases the contact angle to 90±2°. This results in uniform coverage of the PEDOT:PSS on BPhen:C₆₀/Ag NP while maintaining relatively high surface energy. The RCZ, therefore, effectively protects the VTE front cell from the penetration by the solution-processed back cell active layer.

Multi-Junction Performance and Yield

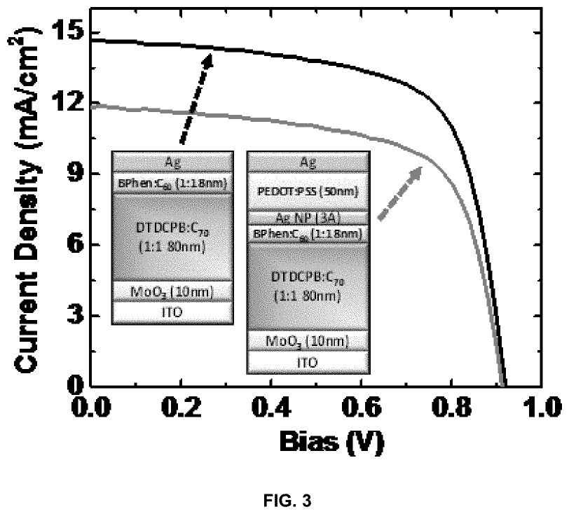

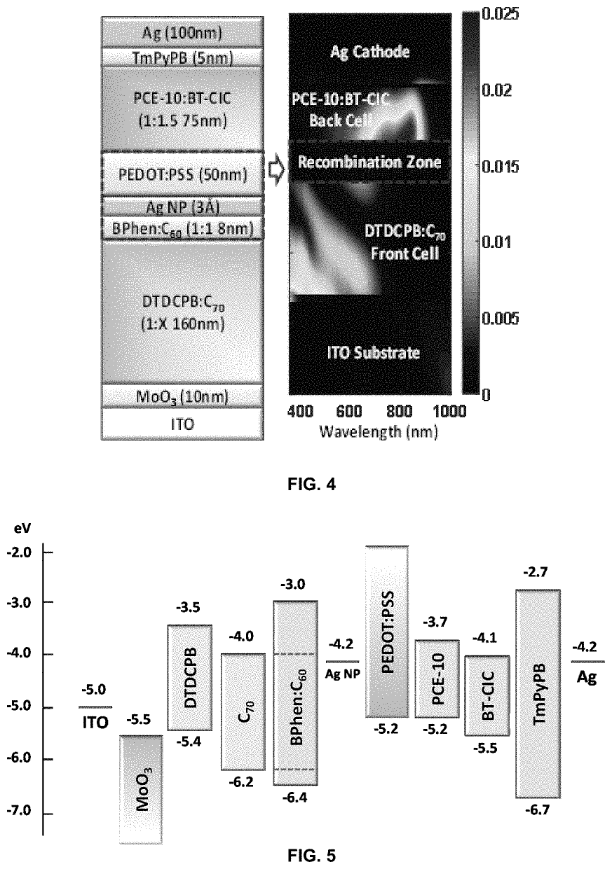

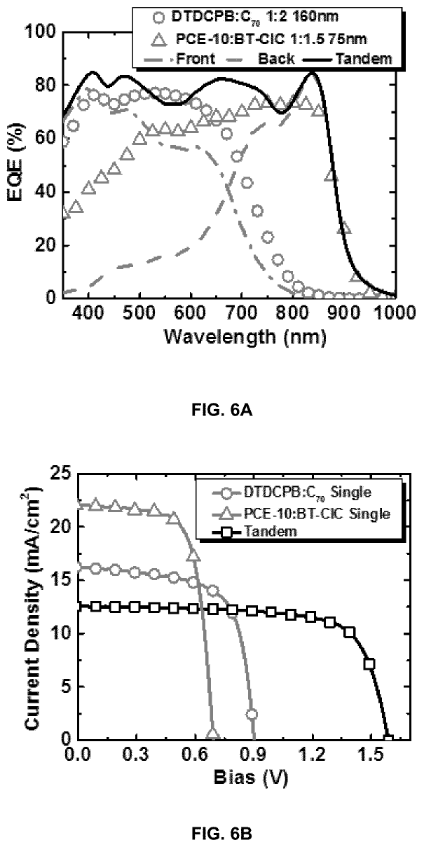

The multi junction or tandem OPV comprises the NIR NFA-based cell on the surface of the DTDCPB:C₇₀ cell, separated by the PEDOT:PSS/Bphen:C₆₀/Ag NP RCZ, as depicted in the left column of FIG. 4, with the device energy level diagram shown in FIG. 5. The DTDCPB:C₇₀ front cell has a thicker active layer than used in a discrete OPV (>160 nm compared to 80 nm) since it lacks the reflecting metal cathode. The thicker cell therefore absorbs a comparable fraction of the incident illumination as the analogous discrete device. The tandem cell with a 160 nm to 170 nm thick layer of 1:2 DTDCPB:C₇₀ front cell achieves the highest efficiency of 14.3±0.3% under 1 sun, simulated AM 1.5G solar irradiation (see Table 1). The measured EQE spectra of the single junction DTDCPB:C₇₀ (1:2, 160 nm) and PCE-10:BT-CIC (1:1.5, 75 nm) cells are plotted in FIG. 6A (circles and triangles, respectively). The two sub-cells absorb between X=350 nm and 950 nm, both exhibiting a peak EQE >70%. The simulated absorbed power distribution of the cell is displayed in the right column of FIG. 4, with the quantum efficiencies of the front, back and tandem cells shown in FIG. 6A (lines). The tandem cell features a nearly wavelength-independent quantum efficiency close to 80% from X=400 nm to 900 nm. The PCE-10:BT-CIC cell in the tandem exhibits a reduced EQE at X<700 nm compared to the single junction cell due to residual absorption by the DTDCPB:C₇₀ cell. The combination of spectral coverage and efficiency leads to a balanced current and minimal absorption overlap between the two stacked sub-cells.

FIG. 6B shows the J-V characteristics of the optimized tandem cell with 160 nm DTDCPB:C₇₀ thickness, together with the discrete sub-cells. The tandem cell exhibits Jₛ=12.6±0.2 mA/cm², V_{oc}=1.58±0.01 V and PCE=14.3±0.3%, with FF=0.72±0.01 higher than both single junction cells. A further increase of the DTDCPB:C₇₀ thickness to 170 nm increases the J_{sc} to 12.7±0.2 mA/cm² while the FF slightly decreases to 0.71±0.01, achieving a similar efficiency of 14.3±0.3%. The reduction in the tandem cell V_{oc} compared with the sum of the V_{oc} of the sub-cells is smaller than 20 meV, implying that the RCZ is nearly electrically lossless.

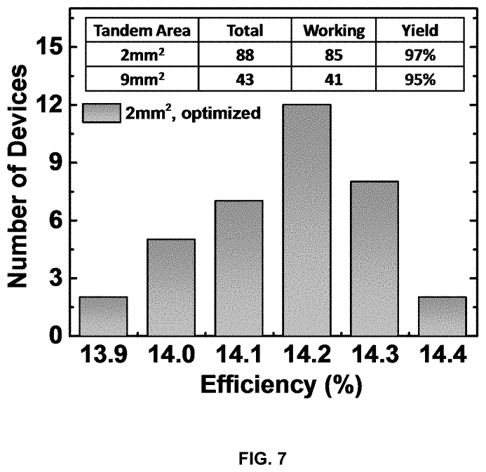

FIG. 7 shows a histogram of PCEs for a population of 36 tandem devices with the optimized structures. The efficiencies fall in a narrow range between 13.9% and 14.4% with the mean value of 14.2. A total population of 88, 2 mm² tandem cells was characterized with results tabulated in the inset of FIG. 7. Of these, 85 devices had a spread in relative efficiencies <3%, corresponding to a 97% device yield. A similar yield of 95% is observed for a population of 43, 9 mm² tandem cells. The hydrophilic-hydrophobic interface between PEDOT:PSS and the underlying films in the recombination zone therefore acts as a robust protecting cap of the VTE films that results in near perfect device yield.

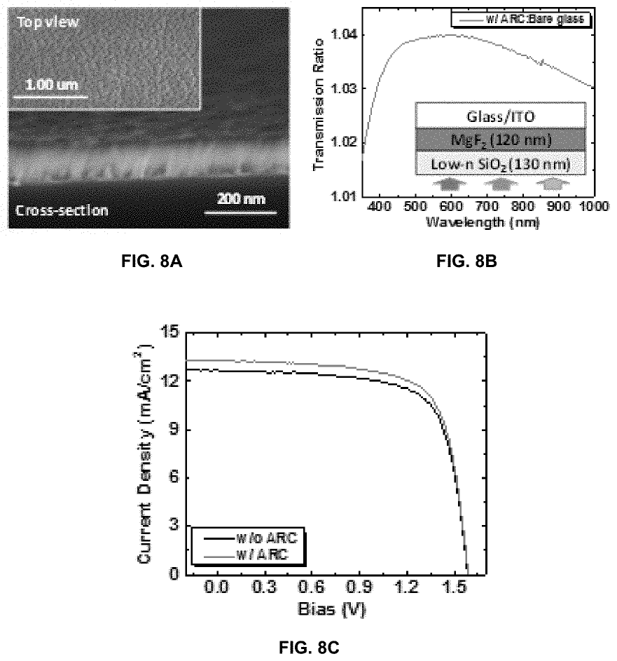

To reduce optical losses, an anti-reflective coating (ARC) consisting of a bilayer of 120 nm MgF₂ (index of refraction, nMgF_{z}=1.38±0.01) and 130 nm low refractive index SiO₂ (nSiO₂=1.12±0.03 obtained via glancing-angle deposition, as discussed in greater detail in the Method section below) is deposited onto the distal surface of the glass substrate. FIG. 8A depicts the SEM top and cross-section views of the SiO₂ film deposited on the Si substrate with an 85° oblique angle.

The transmission ratio of the glass substrate with and without the ARC increases by 3%-4% between X=400 nm and 1000 nm. FIG. 8B depicts the measured transmission ratio between glass substrates with the anti-reflective coating (ARC). FIG. 8C depicts the J-V characteristics of tandem cells with and without ARC. The ARC-coated tandem cell with 170 nm thick 1:2 DTDCPB:C₇₀ shows an increase in J_{sc} from 12.7±0.2 mA/cm² to 13.3±0.3 mA/cm² to achieve PCE =15.0±0.3%. The relative J_{sc} increase is slightly higher than 4%, indicating that the higher incident light transmission also improves the current balance between the two sub-cells.

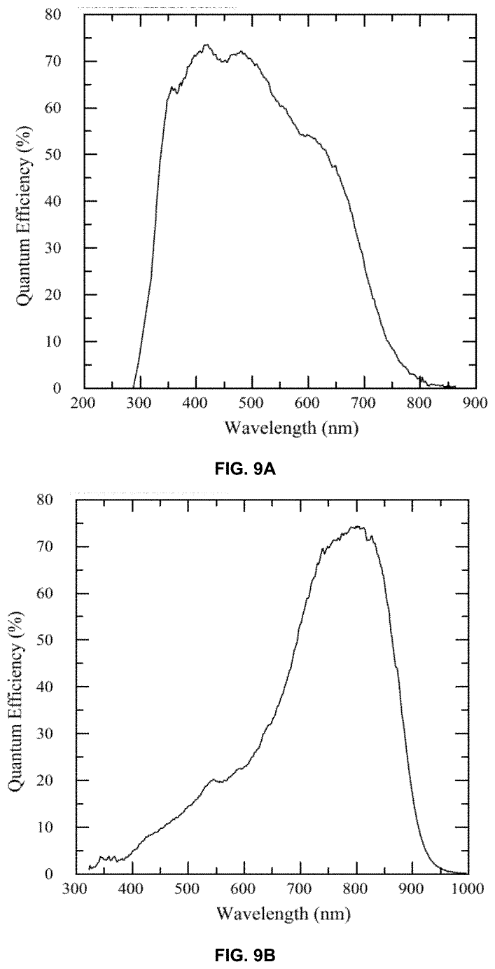

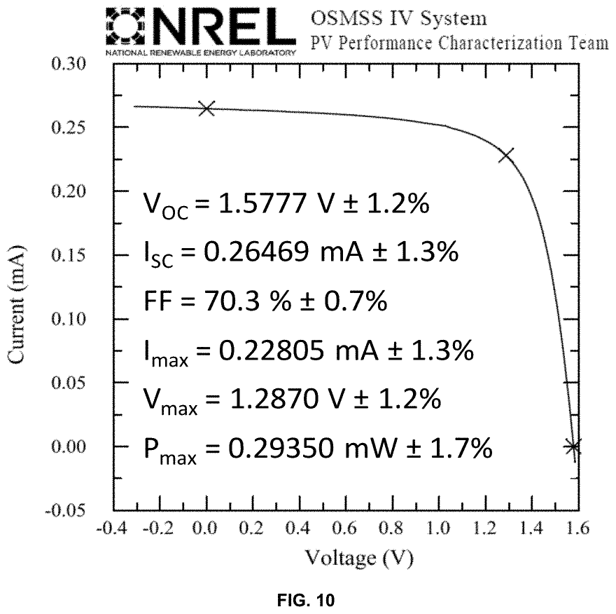

The tandem cells were measured at National Renewable Energy Laboratory (NREL) to cross-check the performances, with the EQE and current-voltage (I-V) data provided in FIGS. 9A, 9B, and 10. Specifically, FIG. 9A depicts the quantum efficiency of DTDCPB:C₇₀ front cell, FIG. 9B depicts the quantum efficiency of PCE-10:BT-CIC back cell, and FIG. 10 depicts the tandem cell current-voltage characteristics (2 mm² device with ARC). The ARC coated tandem cell gives PCE=14.7±0.3%, which is within experimental and statistical errors of results obtained on similar cells in our laboratory.

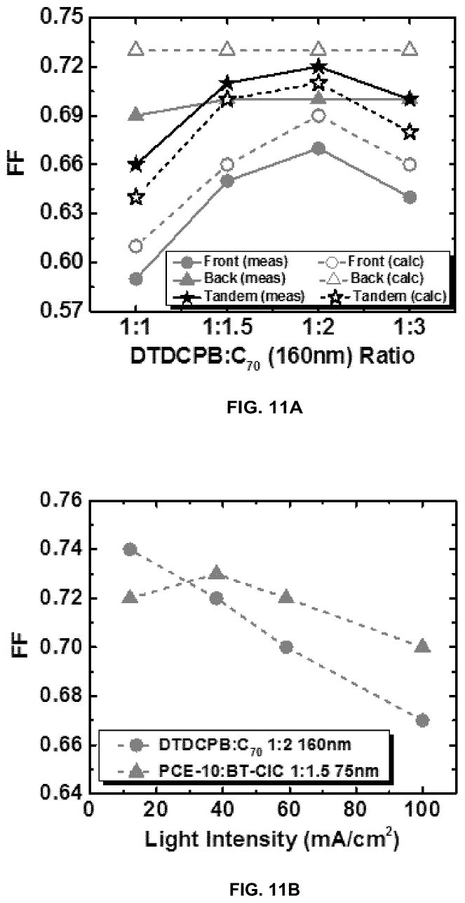

The tandem cells exhibit FF >0.7 which is higher than both single junction cells, contributing significantly to the PCE. To understand this phenomenon, the measured and calculated FFs of the tandems and sub-cells with different DTDCPB:C₇₀ ratios are plotted in FIG. 11A. The solid circles and triangles represent the measured values of the single junction DTDCPB:C₇₀ (160 nm) and PCE-10:BT-CIC (75 nm) cells under AM 1.5G, one sun illumination. FIG. 11B plots the measured FF of the two cells as a function of incident light intensity from 0.1 to 1 sun. Both sub-cells show increasing FF with lower light intensity due to reduced bimolecular recombination at smaller current densities. When the two cells are stacked in tandem, the light intensity and current within each sub-cell is smaller than in the discrete single junction cells. The calculated FFs of the sub-cells in the stack shown in FIG. 11A are therefore higher than their single junction counterparts. According to optical simulations, the front DTDCPB:C₇₀ is operated at an equivalent 0.7 to 0.8 sun intensity that results in an increase in FF by as much as 0.02 (open circles); the back PCE-10:BT-CIC cell operates at a relatively low intensity of ˜0.5 sun corresponding to FF=0.73±0.02 (open triangles). The calculated tandem FF (open stars) lies between the calculated FFs of the two sub-cells and matches with the measured values (solid stars) within the simulation error (±0.02), confirming that the higher tandem FF is due to the reduced light intensity within each sub-cell.

The thermodynamic efficiency limit of single junction OPVs has been shown to be between 22% and 27%, with the actual value determined by the energy loss from exciton and polaron pair binding subsequent to their optical generation.26 Multijunction solar cells can outperform the single junction thermodynamic limit, which suggests that there is large room for improvements in the OPV efficiency described here. For example, NFAs-based OPVs exhibit efficient charge separation with a relatively small energy loss (ELOSS <0.6 eV) compared to ELOSS=0.7-0.8 eV for fullerene-based cells. By replacing the fullerene acceptor of the front cell with an NFA, the tandem V_{oc} can be increased by approximately 0.2 V. In addition, the NFA-based back cell FF is as high as 0.70 due to ordered intermolecular stacking of the planar molecules, leading to a tandem FF=0.72. Thus, increasing the front cell FF from 0.67 to above 0.7, again through replacement of the fullerene with an NFA, a tandem FF=0.75 is likely to be achieved. Further, the average tandem QE still has room for improvement from 80% to >90% by stacking of three or more sub-cells using the variety of deposition techniques. Based on these assumptions, we can expect a 20% relative increase in efficiency of multijunction OPVs to PCE ˜18% in the near future.

In summary, a high efficiency tandem OPV structure has been demonstrated with the NIR-absorbing NFA-based PCE-10:BT-CIC back cell spin-coated onto the visible-absorbing VTE-grown DTDCPB:C₇₀ front cell. The cell broadly absorbs the solar spectrum between X=350 nm and 950 nm. The PEDOT:PSS is introduced in the charge recombination zone between the sub-cells that protects the VTE-grown cell from damage during the solution deposition of the NFA active layer, resulting in >95% tandem device yield. Further, the RCZ comprising the PEDOT:PSS cap on a Ag NP layer adjacent to a BPhen: C₆₀ electron filtering exciton blocking layer is nearly optically and electrically lossless. The ARC-coated tandem cell achieves a maximum PCE=15.0±0.3%. The combination of VTE deposition and solution processing, along with fullerene and NFA sub-cells provides design and fabrication routes previously unavailable to the fabrication of multijunction OPVs. An NFA-based OPV multijunction efficiency of ˜18% is projected based on the design principles demonstrated here.

Methods

Materials. All devices were grown on patterned indium tin oxide (ITO) substrates with sheet resistance of 15 Ω/γ. The acceptor, BT-CIC, was synthesized. Other materials were purchased from commercial suppliers: MoO₃ (Acros Organics); DTDCPB, BPhen and TmPyPB (Luminescence Technology Corp.); C₇₀ (SES Research); C₆₀ (MER); PEDOT:PSS (Clevios P VP AI. 4083, Heraeus); PCE-10 (1-Material); Ag (Alfa Aesar). DTDCPB, C₆₀ and C₇₀ were purified once by temperature-gradient sublimation prior to deposition.

Solar cell fabrication. Pre-patterned ITO on glass substrates were cleaned using a series of detergents and solvents, and exposed to ultraviolet-ozone for 10 minutes before growth. The vacuum-deposited layers for the front cell were grown at ˜1 Å/s in a high vacuum chamber with a base pressure of 2×10⁻⁷ ton. During co-deposition of the VTE-grown blended active regions, the deposition rate of each material is monitored by individual crystal sensors to achieve the desired volume ratios. The vacuum chamber is connected to glove boxes filled with ultrapure N₂ (O₂, H₂O<0.1 ppm) where the solution processed layers were subsequently deposited. The PEDOT:PSS was filtered once with a 0.45 μm Nylon syringe filter prior to use, and then spin-coated onto the substrate at 5000 rpm for 60 seconds. The non-fullerene active layer, PCE-10:BT-CIC (1:1.5 by weight), was dissolved in chlorobenzene:chloroform (CB:CF, 10:1 by vol.) with a concentration of 16 mg/ml. The solution was stirred overnight on a hot plate at 65° C., and then spin-coated at 2000 rpm for 90 seconds to achieve a thickness of 75-80 nm. The samples were then transferred back to the vacuum chamber for deposition of TmPyPB and the Ag cathode. The device areas of 2 mm² or 9 mm² were defined by the overlap between the patterned ITO and the Ag cathode defined by a shadow mask. The ARC was grown onto the glass substrate after the devices were complete. MgF₂ was deposited by VTE while the SiO₂ was grown by electron beam deposition with the substrate at an angle of 85° to the beam direction to achieve a low refractive index of 1.124, 25 (see scanning electron microscope image depicted in FIG. 8A).

Solar cell characterization. The current density-voltage (J-V) characteristics and external quantum efficiencies (EQE) of the cells were measured in a glovebox filled with ultrapure N₂. The EQE measurements were performed with devices underfilled by a 200 Hz-chopped monochromated and focused beam from a Xe lamp. The current output from the devices as well as from a reference NIST-traceable Si detector were recorded using a lock-in amplifier. Light from a Xe lamp filtered to achieve a simulated AM 1.5G spectrum (ASTM G173-03) was used as the source for J-V measurements. The lamp intensity controlled by neutral density filters was calibrated by a Si reference cell certified by National Renewable Energy Laboratory (NREL). Each cell was measured under six different light intensities from 0.001 sun to 1 sun (100 mW/cm²). The J_{sc} of the single junction cells in Table 1 were calculated from the EQE spectrum, with <5% relative mismatch of the measured J_{sc} from J-V characteristics for the DTDCPB: C₇₀ cell, and <7% for the PCE-10:BT-CIC cell. The error bars quoted in the tables take into account both the random and systematic errors. Optical simulations of the single and multijunction cells are based on the transfer matrix method and measurments of the J-V characteristics of the individual sub-cells following previous methods.

The performance of 9 mm² tandem cells are found in Table 2, with ˜2% (relative) lower efficiency than the 2 mm² devices due to the reduced FF. The differences are due to variations between batches of commercially supplied ITO. Efficiencies of both the 2 mm² and 9 mm² tandem cells encapsulated in the N₂ filled glovebox by sealing a glass lid to the substrate using a bead of UV cured epoxy around its periphery were verified by NREL. For quantum efficiency measurements, the NIR-absorbing back cell was biased by an unfiltered red-rich Xe lamp while the visible-absorbing front cell was biased by a Xe lamp with a 600 nm short wavelength passband filter. The current-voltage (I-V) characteristics (unmasked) were then measured by the One-Sun Multi-Source Simulator (OSMSS). The solar simulator spectrum was adjusted based on the measured EQE to achieve the same mismatch factor for all sub-cells (between 0.997 to 1.005). The extracted efficiencies of the 2 mm² and 9 mm² tandems with ARC (four cells each) are listed in Table 3. The same cells were measured in our lab with and without a mask. The J_{sc} with the mask is ˜2% lower than the unmasked case, which is likely due to the non-negligible mask thickness compared with the aperture size.

TABLE 2
9 mm² tandem device performances

| | J_{SC} | V_{OC} | | PCE |
|---|---|---|---|---|
| Tandem (9 mm²) | (mA/cm²) | (V) | FF | (%) |
| w/o ARC | 12.7 ± 0.2 | 1.57 ± 0.01 | 0.70 ± 0.01 | 14.0 ± 0.3 |
| w/ARC | 13.2 ± 0.3 | 1.57 ± 0.01 | 0.70 ± 0.01 | 14.5 ± 0.3 |

TABLE 3
Extracted efficiencies of 8 tandem cells (with ARC)

| Tandem Area | #1 | #2 | #3 | #4 |
|---|---|---|---|---|
| 2 mm² | 14.7% | 14.6% | 14.6% | 14.7% |
| 9 mm² | 14.4% | 14.3% | 14.4% | 14.3% |

While the present claim scope has been described with reference to specific examples, which are intended to be illustrative only and not to be limiting of the claim scope, it will be apparent to those of ordinary skill in the art that changes, additions and/or deletions may be made to the disclosed embodiments without departing from the spirit and scope of the claims.

The foregoing description is given for clearness of understanding only, and no unnecessary limitations should be understood therefrom, as modifications within the scope of the claims may be apparent to those having ordinary skill in the art.

1. A solar cell comprising:
an anode;
a cathode;
a first active layer positioned between the anode and the cathode, the first active layer configured to absorb light in a first wavelength spectrum,
a second active layer positioned between the anode and the cathode, the second active layer configured to absorb light in a second wavelength spectrum; and
a recombination zone positioned between the first active layer and the second active layer.

2. The solar cell of claim 1, further comprising:
a third active layer positioned between the anode and the cathode, the third active layer configured to absorb light in a third wavelength spectrum; and
an additional recombination zone positioned between the second active layer and the third active layer.

3. The solar cell of claim 1, further comprising:
at least one additional active layer positioned between the anode and the cathode, the at least one additional active layer configured to absorb light in at least one additional wavelength spectrum; and
a corresponding number of additional recombination zones positioned between adjacent active layers.

4. The solar cell of claim 1, wherein the first wavelength spectrum comprises at least a portion of a visible light spectrum, and
wherein the second wavelength spectrum comprises at least a portion of a near-infrared light spectrum.

5. The solar cell of claim 1, wherein the first active layer is positioned between the anode and the recombination zone, and
wherein the second active layer is positioned between the cathode and the recombination zone.

6. The solar cell of claim 1, wherein the first active layer comprises a fullerene acceptor, and
wherein the second active layer comprises a non-fullerene acceptor.

7. The solar cell of claim 6, wherein the fullerene acceptor is C₆₀ or C₇₀, and
wherein the non-fullerene acceptor has the following structure:

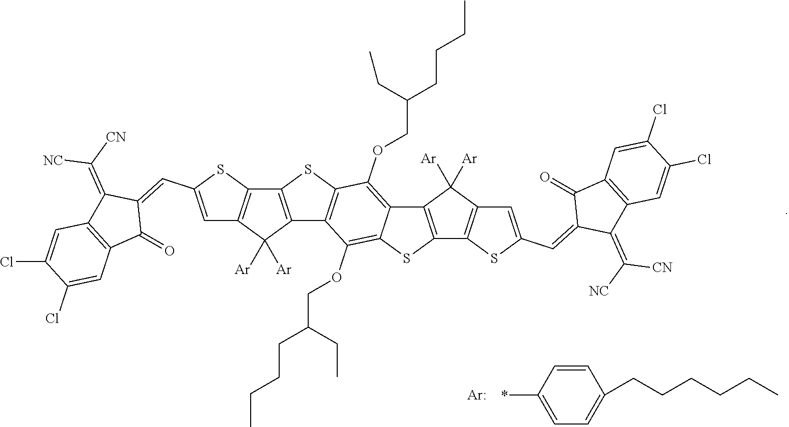

8. The solar cell of claim 1, wherein the first active layer has a thickness of at least 100 nm.

9. (canceled)

10. The solar cell of claim 1, further comprising:
a first buffer layer positioned between the anode and the first active layer; and
a second buffer layer positioned between the second active layer and the cathode.

11. The solar cell of claim 10, wherein the first buffer layer and the second buffer layer are individually metal oxides selected from the group consisting of MoO₃, V₂O₅, ZnO, or TiO₂.

12. The solar cell of claim 10, wherein the first buffer layer or the second buffer layer comprises one or more of the following molecules:

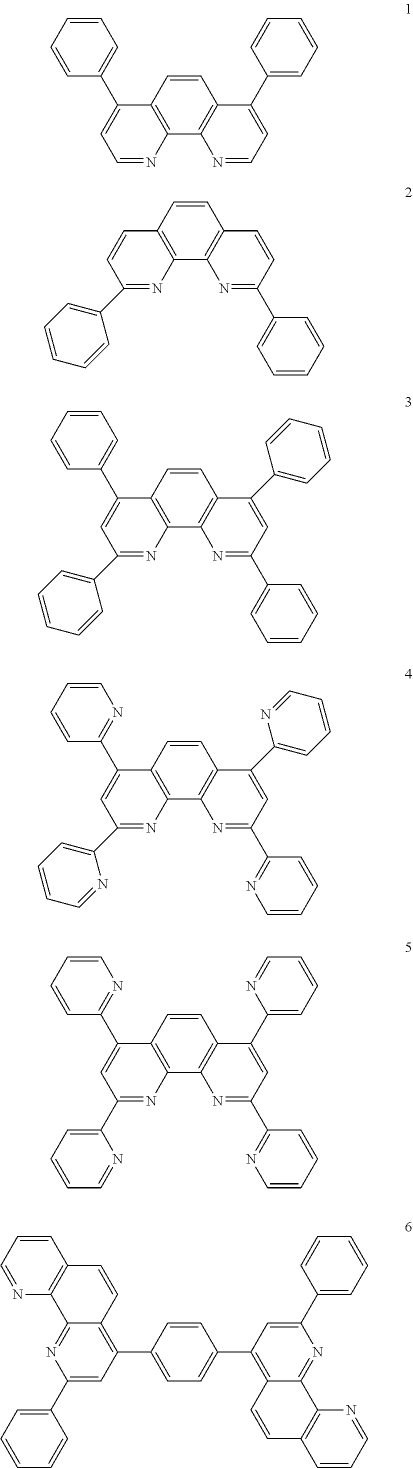

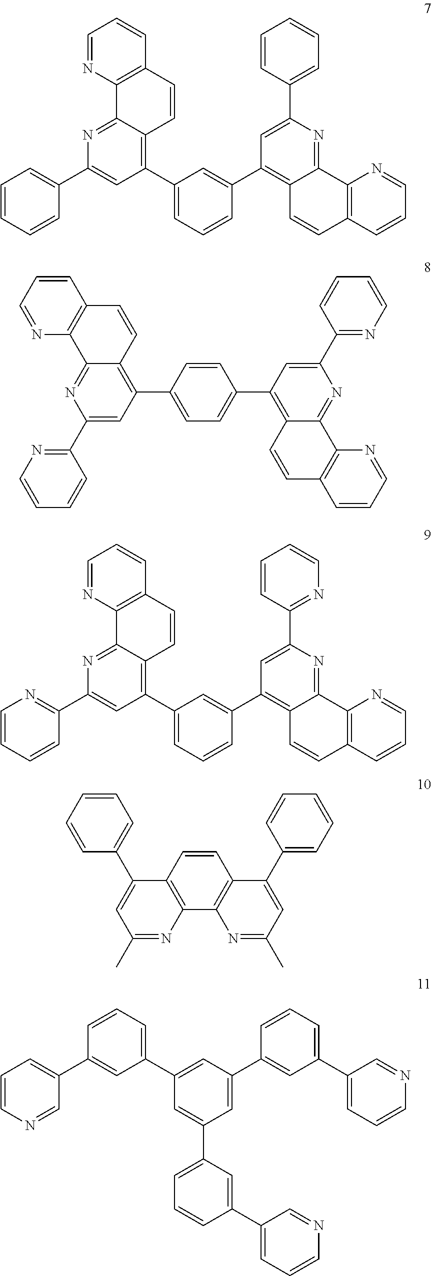

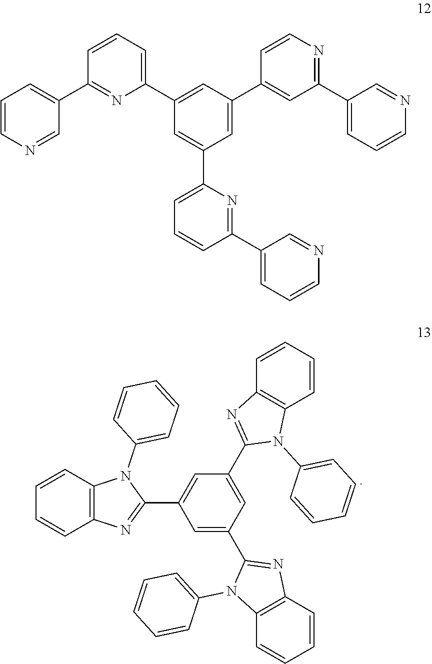

13. (canceled)

14. The solar cell of claim 1, wherein the recombination zone comprises a plurality of layers configured to provide a hydrophilic-hydrophobic interface to prevent solvent penetration from the second active layer into the first active layer.

15. The solar cell of claim 1, wherein the recombination zone comprises a first layer having a polymer mixture comprising a sulfonated polystyrene and a polythiophene.

16. (canceled)

17. The solar cell of claim 15, wherein the sulfonated polystyrene is a sodium polystyrene sulfonate, and wherein the polythiophene is poly(3,4-ethylenedioxythiophene).

18. (canceled)

19. (canceled)

20. The solar cell of claim 14, wherein the recombination zone comprises a second layer comprising metal nanoparticles, and wherein the polymer mixture of the first layer of the recombination zone is spin coated on the second layer of the recombination zone.

21. (canceled)

22. The solar cell of claim 20, wherein the metal nanoparticles comprise Ag, Au, Pd, Pt, Ti, V, Zn, Sn, Al, Co, Ni, Cu, Cr, or combinations thereof.

23. (canceled)

24. The solar cell of claim 20, wherein the recombination zone comprises a third layer comprising a mixture of a phenanthroline and a fullerene, and
wherein the second layer of the recombination zone is positioned between the first layer of the recombination zone and the third layer of the recombination zone.

25. (canceled)

26. The solar cell of claim 24, wherein the phenanthroline is bathophenanthroline.

27. The solar cell of claim 1, further comprising an anti-reflective coating positioned on an exterior surface of the anode or the cathode.

28. The solar cell of claim 27, wherein the anti-reflective coating comprises a plurality of layers with alternating layers of contrasting refractive index, and
wherein the plurality of layers comprises a first layer having magnesium fluoride and a second layer having silicon oxide.

29. (canceled)
